(19) United States
(12) Patent Application Publication
(10) Pub. No.: US 2025/0357455 A1
(43) Pub. Date: Nov. 20, 2025

(54) PACKAGE STRUCTURE WITH HEAT SPREADER LAYER AND METHOD FOR MANUFACTURING THE SAME

(71) Applicant: Taiwan Semiconductor Manufacturing Co., Ltd., Hsinchu (TW)

(72) Inventors: Yi-Hsuan Wu, Miaoli County (TW); Lipu Kris Chuang, Hsinchu (TW)

(21) Appl. No.: 19/284,788

(22) Filed: Jul. 30, 2025

Related U.S. Application Data
(63) Continuation of application No. 18/619,850, filed on Mar. 28, 2024.
(60) Provisional application No. 63/613,170, filed on Dec. 21, 2023.

(51) Int. Cl. H01L 25/18; H01L 23/00; H01L 23/31; H01L 23/367; H01L 23/373; H01L 23/498; H01L 25/00

(52) U.S. Cl. CPC H01L 25/18; H01L 23/3128; H01L 23/367; H01L 23/373; H01L 23/49833; H01L 23/49838; H01L 24/16; H01L 24/32; H01L 24/73; H01L 25/50; H01L 2224/16227; H01L 2224/16238; H01L 2224/32225; H01L 2224/73204; H01L 2924/1815

(57) ABSTRACT

A package structure and method for manufacturing the same are provided. The package structure includes a first redistribution structure and a first package component and a second package component attached to a first side of the first redistribution structure and spaced apart from each other. The package structure further includes a first semiconductor die attached to a second side of the first redistribution structure and an encapsulant. The package structure further includes a heat spreader layer formed over the first semiconductor die, and a thermal conductivity of the heat spreader layer is greater than a thermal conductivity of the encapsulant. The package structure further includes a conductive feature formed through the heat spreader layer and a second redistribution structure formed over the heat spreader layer. In addition, the second redistribution structure is electrically connected to the first semiconductor die through the conductive feature.

### PRIORITY CLAIM AND CROSS-REFERENCE

This application is a continuation of U.S. patent application Ser. No. 18/619,850, filed on Mar. 28, 2024, which claims priority to U.S. Provisional Application No. 63/613,170, filed on Dec. 21, 2023, the entirety of each is incorporated by reference herein.

### BACKGROUND

The semiconductor integrated circuit (IC) industry has experienced rapid growth. Continuing advances in semiconductor manufacturing processes have resulted in semiconductor devices with finer features and/or higher degrees of integration. Functional density (i.e., the number of interconnected devices per chip area) has generally increased while feature sizes (i.e., the smallest component that can be created using a fabrication process) have decreased. This scaling-down process generally provides benefits by increasing production efficiency and lowering associated costs.

A chip package not only provides protection for semiconductor devices from environmental contaminants, but also provides a connection interface for the semiconductor devices packaged therein. Smaller package structures, which take up less space or are lower in height, have been developed to package the semiconductor devices.

New packaging technologies have been developed to further improve the density and functionality of semiconductor dies. These relatively new types of packaging technologies for semiconductor dies face manufacturing challenges.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A to 1C illustrate diagrammatic top views of a package structure in accordance with some embodiments.

FIGS. 2A to 2P illustrate cross-sectional views of intermediate stages of manufacturing the package structure in accordance with some embodiments.

FIG. 2N-1 illustrates an enlarged cross-sectional view of the region R_2N shown in FIG. 2N in accordance with some embodiments.

FIG. 2O-1 illustrates conductive features formed in the openings in accordance with some embodiments.

FIG. 2O-2 illustrate conductive features formed in the openings in accordance with some embodiments.

FIG. 2P-1 illustrates the package structure including the conductive features as shown in FIG. 2O-1 in accordance with some embodiments.

FIG. 2P-2 illustrates the package structure including the conductive features as shown in FIG. 2O-2 in accordance with some embodiments.

FIG. 3 illustrates a cross-sectional view of a package structure in accordance with some embodiments.

FIG. 4A illustrates an enlarged cross-sectional view of the region R_3a shown in FIG. 3 in accordance with some embodiments.

FIG. 4B illustrates an enlarged cross-sectional view of the region R_3b shown in FIG. 3 in accordance with some embodiments.

FIG. 5A illustrates an enlarged cross-sectional view of the region R_3a shown in FIG. 3 in accordance with some other embodiments.

FIG. 5B illustrates an enlarged cross-sectional view of the region R_3b shown in FIG. 3 in accordance with some other embodiments.

FIG. 6 illustrates a diagrammatic top view of a package structure in accordance with some embodiments.

FIG. 7A illustrates a diagrammatic top view of a package structure in accordance with some embodiments.

FIG. 7B illustrates a cross-sectional view of the package structure shown along line X_{7A}-X_{7A}′ in FIG. 7A in accordance with some embodiments.

FIG. 8 illustrates a diagrammatic top view of a package structure in accordance with some embodiments.

FIG. 9A illustrates a diagrammatic top view of a package structure in accordance with some embodiments.

FIG. 9B illustrates a cross-sectional view of the package structure along line X_{9A}-X_{9A}′ in accordance with some embodiments.

FIG. 9C illustrates a cross-sectional view of a package structure in accordance with some embodiments.

FIG. 10 illustrates a diagrammatic top view of a package structure in accordance with some embodiments.

FIG. 11A illustrates a diagrammatic top view of a package structure in accordance with some embodiments.

FIG. 11B illustrates a diagrammatic top view of a package structure in accordance with some embodiments.

FIG. 12A illustrates a diagrammatic top view of a package structure in accordance with some embodiments.

FIG. 12B illustrates a diagrammatic top view of a package structure in accordance with some embodiments.

FIG. 13A illustrates a diagrammatic top view of a package structure in accordance with some embodiments.

FIG. 13B illustrates a cross-sectional view of the package structure along line X_{13A}-X_{13A}′ in accordance with some embodiments.

FIG. 13C illustrates a cross-sectional view of a package structure in accordance with some embodiments.

FIG. 14 illustrates a diagrammatic top view of a package structure in accordance with some embodiments.

FIG. 15 illustrates a diagrammatic top view of a package structure in accordance with some embodiments.

FIG. 16 illustrates a diagrammatic top view of a package structure in accordance with some embodiments.

FIG. 17 illustrates a diagrammatic top view of a package structure in accordance with some embodiments.

FIG. 18 illustrates a diagrammatic top view of a package structure in accordance with some embodiments.

FIG. 19 illustrates a diagrammatic top view of a package structure in accordance with some embodiments.

FIG. 20 illustrates a diagrammatic top view of a package structure in accordance with some embodiments.

FIG. 21 illustrates a diagrammatic top view of a package structure in accordance with some embodiments.

FIG. 22 illustrates a diagrammatic top view of a package structure in accordance with some embodiments.

FIG. 23 illustrates a diagrammatic top view of a package structure in accordance with some embodiments.

FIG. 24 illustrates a diagrammatic top view of a package structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the disclosure may relate to package structures such as three-dimensional (3D) packaging, 3D-IC devices, and 2.5D packaging. Embodiments of the disclosure form a package structure including a substrate that carries one or more dies or packages and a protective element (such as a protective lid) aside the dies or packages. The protective element may also function as a warpage-control element and/or heat dissipation element.

Other features and processes may also be included. For example, testing structures may be included to aid in the verification testing of the 3D packaging, 3DIC devices, and/or 2.5 D packaging. The testing structures may include, for example, test pads formed in a redistribution layer or on a substrate that allows testing to be conducted using probes or probe cards and the like. Verification testing may be performed on intermediate structures as well as the final structure. Additionally, the structures and methods disclosed herein may be used in conjunction with testing methodologies that incorporate intermediate verification of known good dies to increase the yield and decrease costs.

A package structure may include various package components and semiconductor dies electrically connected to the package components. These semiconductor dies may be generate heat during the operation and may be seen as the hot spots in the devices. Accordingly, a heat spreader layer is formed over the semiconductor dies, so that the temperature at the semiconductor dies may be spread (e.g. dissipated) through the heat spreader layer. In addition, the temperature of the package components may therefore be decreased during operation.

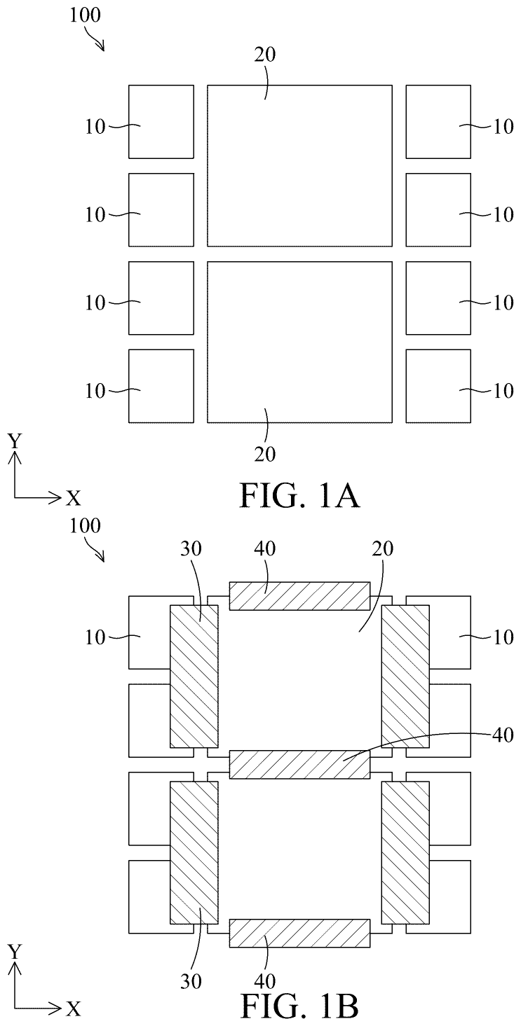

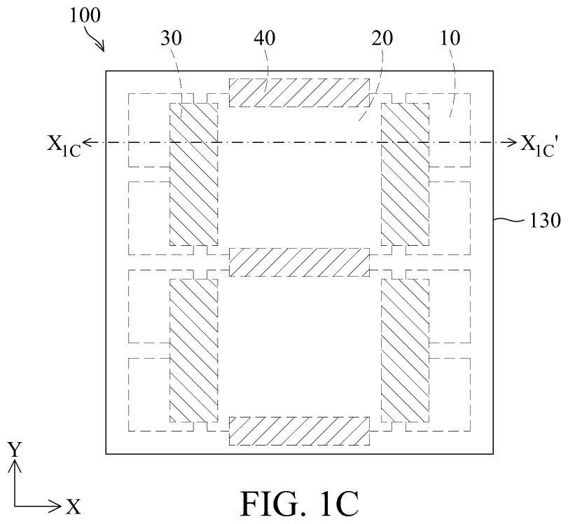

FIGS. 1A to 1C illustrate diagrammatic top views of a package structure 100 in accordance with some embodiments. For a better understanding of the structure, the X-Y-Z coordinate reference is provided in the following figures. In addition, the following figures may have been simplified for the sake of clarity to better understand the inventive concepts of the present disclosure. Additional features may be included, and some of the features described below may be replaced, modified, or eliminated.

More specifically, FIG. 1A illustrates the layout of package components 10 and 20 in the package structure 100 in accordance with some embodiments. In some embodiments, the package components 10 and 20 are semiconductor dies with different functions. In some embodiments, the package components 10 include a memory device, such as a hybrid memory cube (HMC) module, a high bandwidth memory (HBM) module, or the like that includes multiple memory dies. In some embodiments, the package components 20 include system on chip (SoC) dies, chip scale packages (CSP), or a combination thereof. In some embodiments, the package components 10 are HBM dies and the package components 20 are SoC dies.

In some embodiments, one of the package component 20 is sandwiched between two of the package components 10 in X direction, as shown in the top view in FIG. 1A. In some embodiments, one of the package component 20 and two of the package components 10 are aligned with each other in the X direction. In some embodiments, the package components 10 are aligned with each other in the Y direction, and the package components 20 are aligned with each other in the Y direction. The package components 10 and 20 may be formed over a redistribution structure (not shown in FIG. 1A) and the detail of the processes will be described afterwards.

FIG. 1B further illustrates the layout of semiconductor dies 30 and 40 in the package structure 100 in accordance with some embodiments. More specifically, the semiconductor dies 30 and 40 are embedded active dies and are electrically coupled to the package components 10 and 20 through a redistribution structure. In some embodiments, the semiconductor dies 30 and 40 are embedded local interconnect dies.

In some embodiments, each of the semiconductor dies 30 is configured to provide electrical connection between two of the package components 10 and one of the package components 20 in X direction. In some embodiments, each of the semiconductor dies 30 partially overlaps two of the package components 10 and one of the package components 20 in the top view, as shown in FIG. 1B. In some embodiments, each of the semiconductor dies 30 partially overlaps two adjacent sidewall surfaces of two package components 10 and one sidewall surface of one package component 20 in the top view. In some embodiments, each of the semiconductor dies 40 are configured to provide electric connection between two of the package components 20 in Y direction. In some embodiments, each of the semiconductor dies 40 vertically overlaps two of the package components 20 in the top view, as shown in FIG. 1B.

FIG. 1C further illustrates the layout of a heat spreader layer 130 in the package structure 100 in accordance with some embodiments. In some embodiments, the heat spreader layer 130 is a carbon-containing heat spreader layer. More specifically, the heat spreader layer 130 is formed over the semiconductor dies 30 and 40, so that the heat generate by the semiconductor dies 30 and 40 during the operation can be dissipated and the temperature of the device may be reduced. In some embodiments, the heat spreader layer 130 continuously extends from over the semiconductor dies 30 to over the semiconductor dies 40. In some embodiments, the semiconductor dies 30 and 40 are completely covered by the heat spreader layer 130. In some embodiments, the width of the heat spreader layer 130 is greater than the width of each of the semiconductor dies 30 and 40 in both X direction and Y direction. In some embodiments, the package components 10 and 20 are also completely covered by the heat spreader layer 130 in the top view. In some embodiments, the width of the heat spreader layer 130 is greater than the width of each of the package components 10 and 20 in both X direction and Y direction.

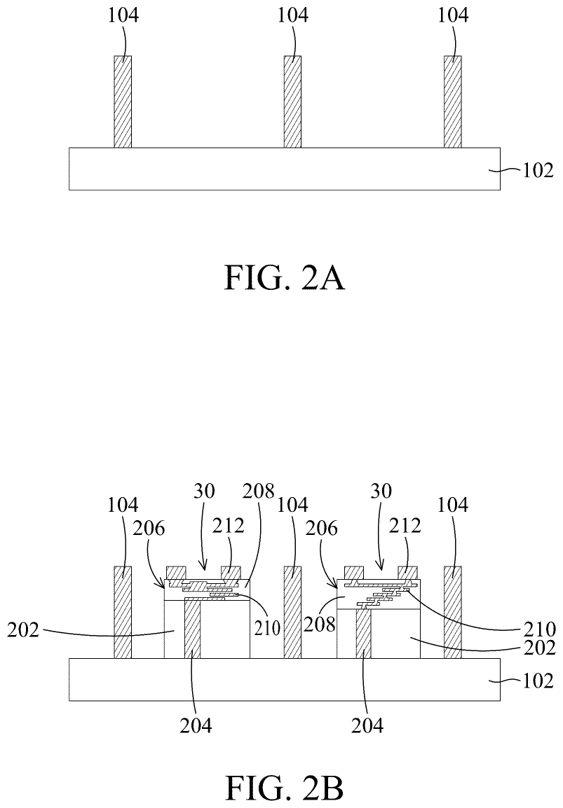

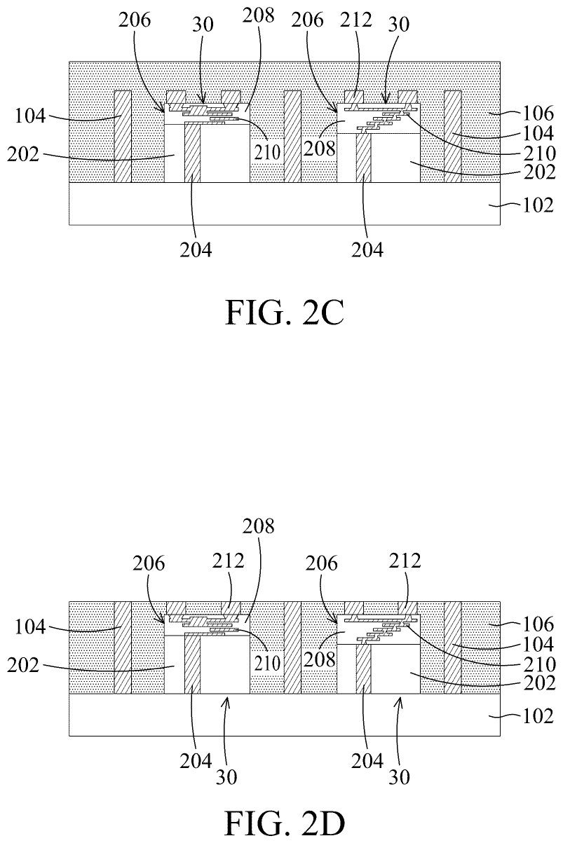

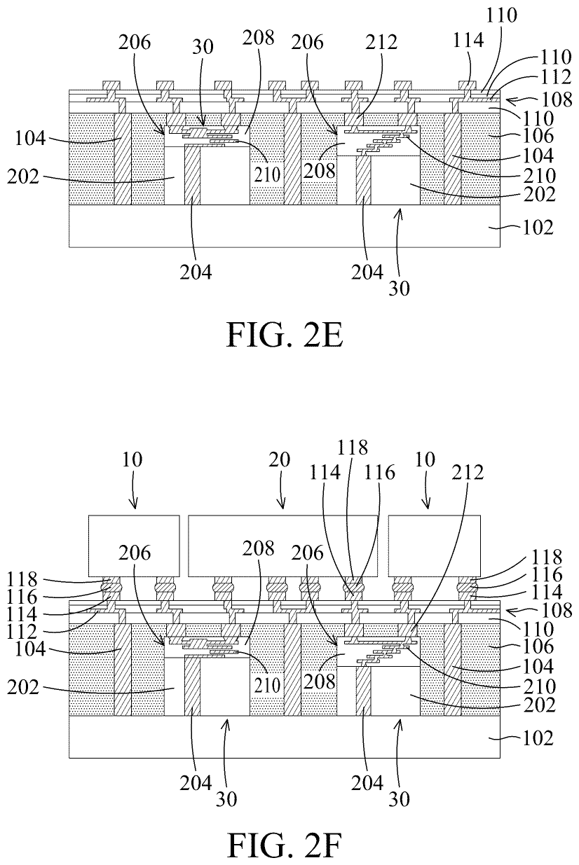

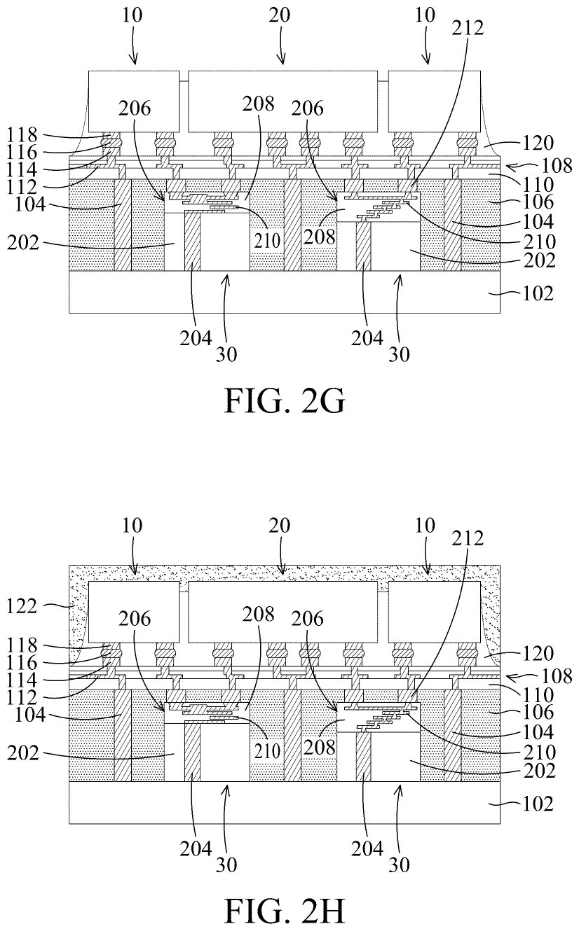

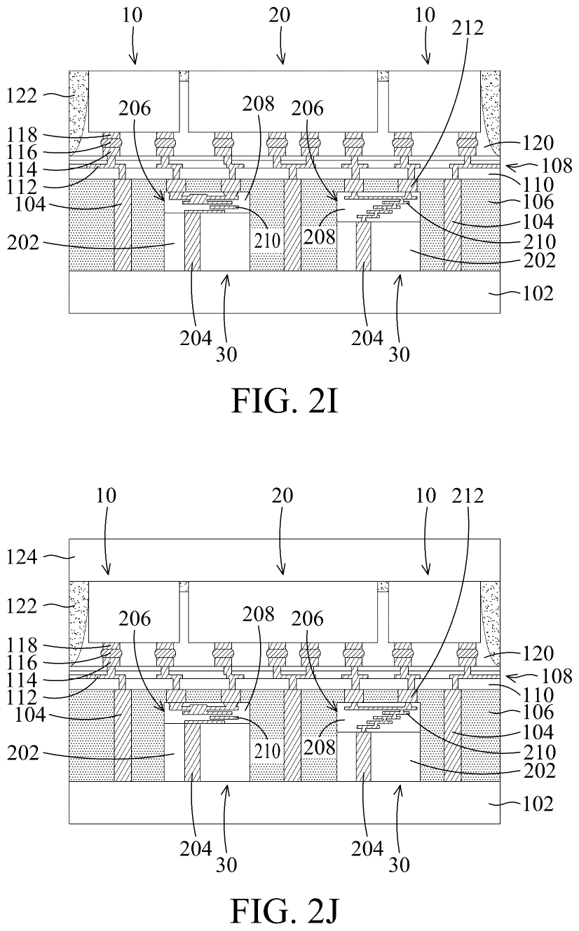

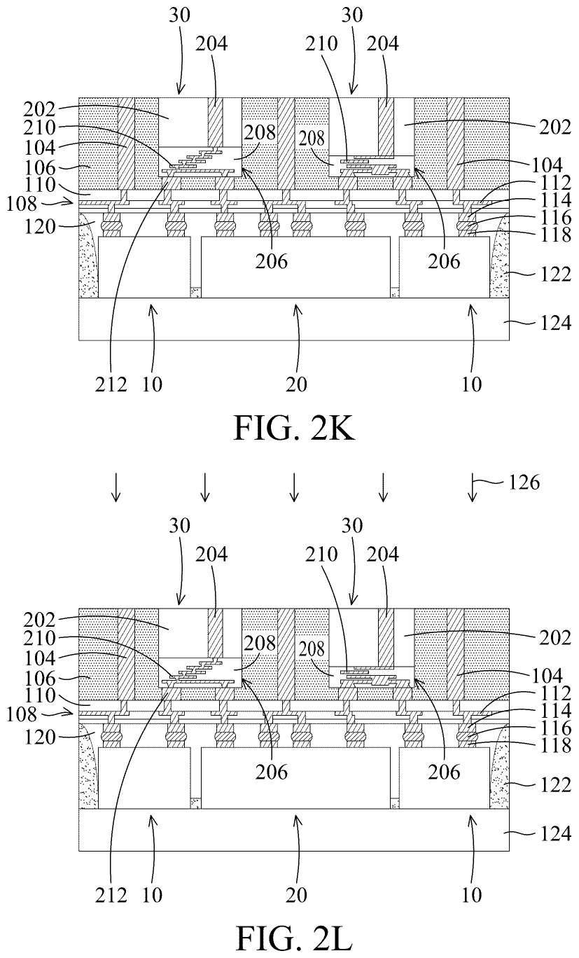

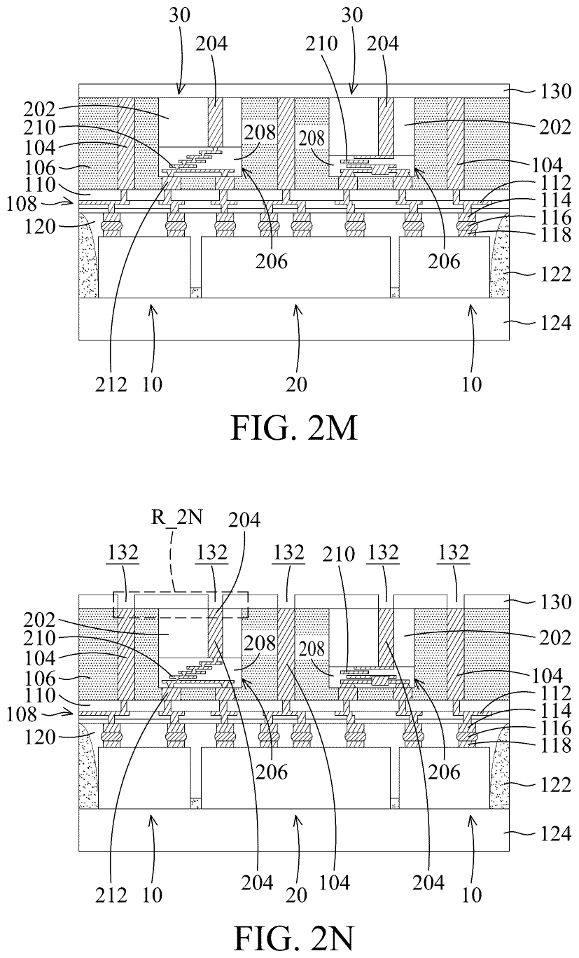

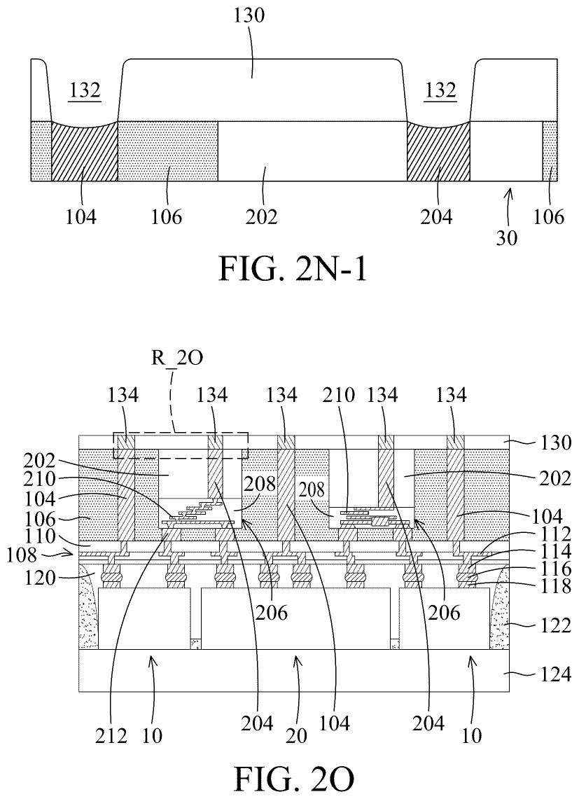

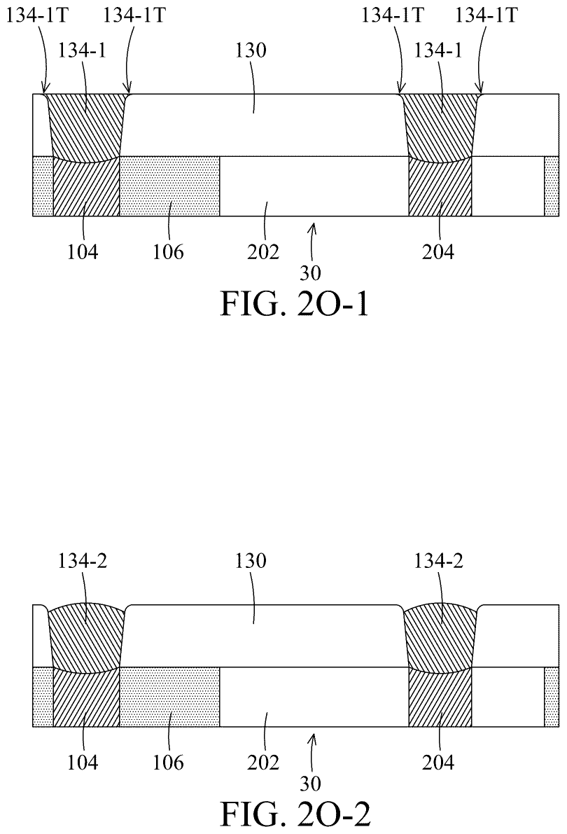

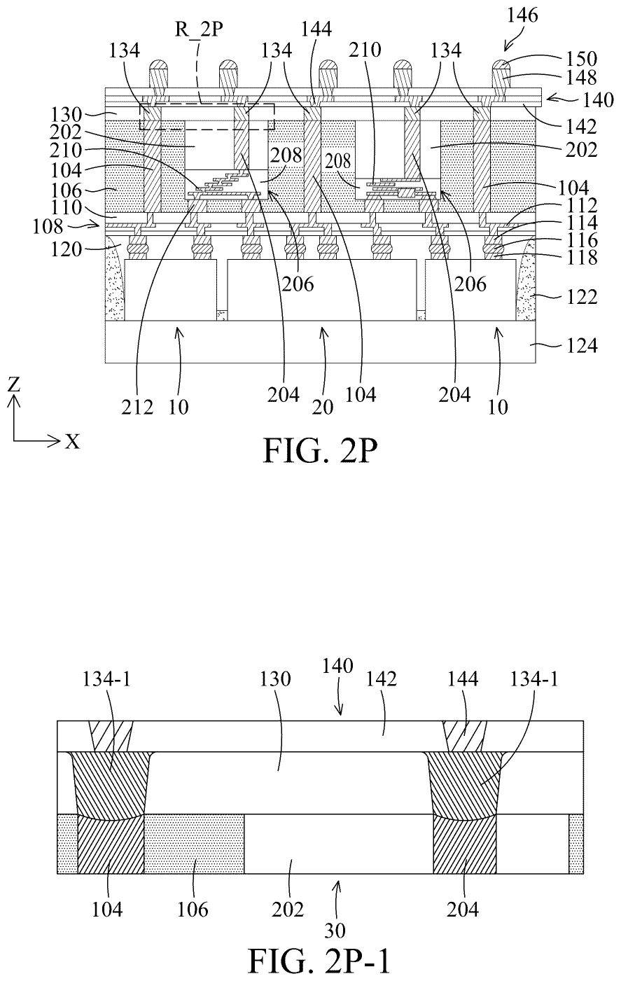

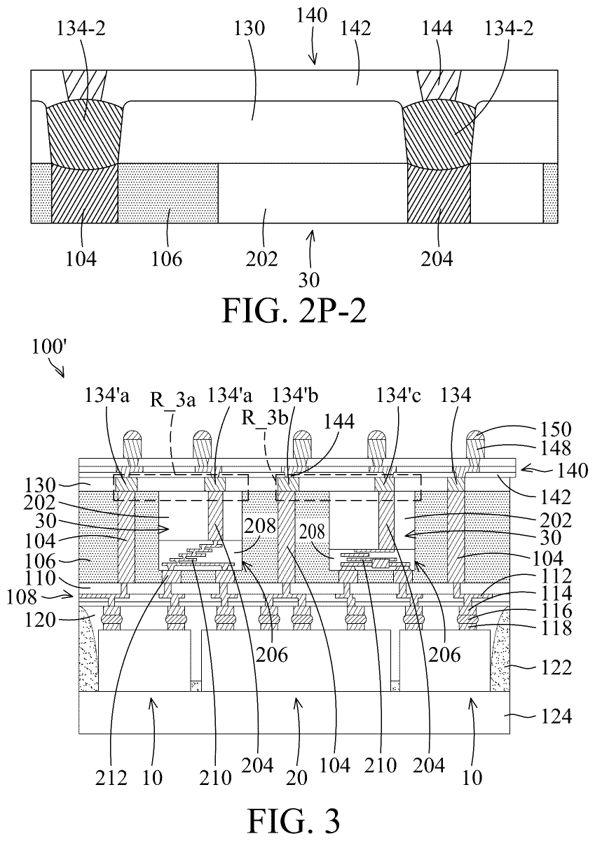

FIGS. 2A to 2P illustrate cross-sectional views of intermediate stages of manufacturing the package structure 100 in accordance with some embodiments. More specifically, the cross-sectional views are shown along line X_{1C}-X_{1C}′ in FIG. 1C in accordance with some embodiments. As shown in FIG. 2A, through insulating vias (TIVs) 104 are formed over a carrier substrate 102 in accordance with some embodiments.

The carrier substrate 102 may be configured to provide structural support during the manufacturing processes of the package structure 100. In some embodiments, the carrier substrate 102 is made of a material such as silicon, polymer, polymer composite, metal foil, ceramic, glass, glass epoxy, beryllium oxide, tape, or other suitable material for structural support. In some embodiments, the carrier substrate 102 is a sapphire glass substrate.

In some embodiments, the through insulating vias 104 are made of a conductive material, such as copper, titanium, tungsten, aluminum, or the like. In some embodiments, seed layers (not shown) are formed before the through insulating vias 104 are formed. The through insulating vias 104 may be formed by the following processes. A photoresist layer may be formed over the carrier substrate 102 by spin coating or the like. The photoresist layer may then be exposed to light for patterning and openings may be formed in the photoresist layer. After the openings are formed, the through insulating vias 104 may be formed in the openings by filling a conductive material in the openings by plating, such as electroplating or electroless plating, or the like. The photoresist may then be removed by an ashing or stripping process, such as using an oxygen plasma or the like.

After the through insulating vias 104 are formed, the semiconductor dies 30 and 40 (not shown in FIG. 2B, see FIG. 1B) are disposed over the carrier substrate 102, as shown in FIG. 2B in accordance with some embodiments. Although the semiconductor dies 40 are not shown in FIG. 2B, the structures of the semiconductor dies 40 may be similar to, or the same as, those of the semiconductor dies 30 shown in FIGS. 2B to 2P and described afterwards. In some embodiments, the through insulating vias 104 are sandwiched between the semiconductor dies 30 and 40 and spaced apart from the semiconductor dies 30 and 40. In some embodiments, some of the semiconductor dies 30 and 40 are formed next to each other without the through insulating vias 104 formed therebetween. In some embodiments, the closest distance between two neighboring semiconductor dies 30 and 40 is in a range from about 50 μm to about 150 μm.

In some embodiments, each of the semiconductor dies 30 and 40 includes a substrate 202, a conductive via 204 formed through the substrate 202, and an interconnect structure 206 formed over the substrate 202. In some embodiments, the interconnect structure 206 includes multiple metallization layers, and the metallization layers includes dielectric layers 208 and conductive structures 210 formed in the dielectric layers 208. The conductive structures 210 may include metal lines and metal vias formed in the dielectric layers 208. In addition, the conductive vias 204 are electrically connected to the conductive structures 210 in the interconnect structure 206 in accordance with some embodiments. In some embodiments, conductive connectors 212 are formed over the interconnect structure 206 and are electrically connected to the conductive structures 210 in the interconnect structure 206. The layout of the conductive structures 210 in the interconnect structures 206 in each of the semiconductor dies 30 and 40 may be the same or different.

The substrate 202 may be a semiconductor substrate, such as silicon, which may be doped or undoped, and which may be a silicon wafer or an active layer of a semiconductor-on-insulator (SOI) substrate, or the like. The substrate 202 may include other semiconductor materials, such as germanium, silicon carbide, gallium arsenic, gallium phosphide, indium phosphide, indium arsenide, indium antimonide, SiGe, GaAsP, AlInAs, AlGaAs, GaInAs, GaInP, GaInAsP, or combinations thereof. Other substrates, such as multi-layered or gradient substrates, may also be used. In some embodiments, the conductive via 204 is formed through the substrate 202 to electrically connect two sides of the substrate 202. In some embodiments, the conductive via 204 is made of W, Ru, Co, Cu, Ti, TiN, Ta, TaN, Mo, Ni, other applicable conductive materials, or a combination thereof.

The interconnect structure 206 may be formed by damascene processes, such as a single damascene process, a dual damascene process, or the like. In some embodiments, the dielectric layers 208 include multiple layers made of low k dielectric materials having a k value lower than 7. In some embodiments, the dielectric layers 208 are made of SiO₂, SiN, SiCN, SiOC, SiOCN, or the like. The dielectric layer 208 may be formed by chemical vapor deposition (CVD), physical vapor deposition, (PVD), atomic layer deposition (ALD), or other applicable processes. In some embodiments, the conductive structures 210 are made of W, Ru, Co, Cu, Ti, TiN, Ta, TaN, Mo, Ni, other applicable conductive materials, or a combination thereof. The conductive structures 210 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

The conductive connectors 212 may include bonding pads, microbumps, copper pillars, copper layers, nickel layers, lead free layers, electroless nickel electroless palladium immersion gold (ENEPIG) layers, Sn/Ag layers, Sn/Pb layers, or the like. In some embodiments, the conductive connectors 212 are electrically connected to the conductive structure 210 in the interconnect structure 206.

After the semiconductor dies 30 and 40 are disposed over the carrier substrate 102, an encapsulant 106 is formed over the carrier substrate 102, as shown in FIG. 2C in accordance with some embodiments. More specifically, the encapsulant 106 is formed to laterally encapsulate the through insulating vias 104 and the semiconductor dies 30 and 40. In some embodiments, the top surfaces of the through insulating vias 104 and the semiconductor dies 30 and 40 are covered by the encapsulant 106 at this step. In some embodiments, the encapsulant 106 include a molding compound such as a resin, polyimide, PPS, PEEK, PES, epoxy molding compound (EMC), or a combination thereof.

After the encapsulant 106 is formed, a planarization process is performed on the encapsulant 106 until the through insulating vias 104 and the conductive connectors 212 are exposed, as shown in FIG. 2D in accordance with some embodiments. The planarization process may be performed to remove excess portions of encapsulant 106 by using a mechanical grinding process, a chemical mechanical polishing (CMP) process, or the like. In some embodiments, the through insulating vias 104 and/or the conductive connectors 212 are also slightly polished during the planarization process. After the planarization process, the top surfaces of the through insulating vias 104 and the conductive connectors 212 are substantially level with the top surface of the encapsulant 106 in accordance with some embodiments.

Next, a redistribution structure 108 is formed over the semiconductor dies 30 and 40, the through insulating vias 104, and the encapsulant 106, and conductive pads 114 are formed over the redistribution structure 108, as shown in FIG. 2E in accordance with some embodiments. In some embodiments, the redistribution structure 108 includes multiple insulating layers 110 and redistribution layers (RDLs) 112, and the redistribution layers 112 are electrically connected to the through insulating vias 104 and the conductive connectors 212 of the semiconductor dies 30 and 40. The redistribution layers 112 may be seen as a fan-out structure. The numbers of the insulating layers 110 and redistribution layers 112 shown in FIG. 2E are merely an example and are not intended to be limited. For example, the numbers of the insulating layers 110 and redistribution layers 112 may be in a range from about 1 to about 15.

In some embodiments, the insulating layer 110 are made of one or more suitable dielectric materials such as an oxide (e.g., silicon oxide), a nitride (e.g., silicon nitride), a polymer material, a polyimide material, a low-k dielectric material, a molding material (e.g., an EMC or the like), another dielectric material, or a combination thereof. The insulation layers 110 may be formed by a process such as spin-coating, lamination, CVD, the like, or a combination thereof. In some embodiments, the redistribution layers 112 are made of a conductive material such as copper, titanium, tungsten, aluminum, or a combination thereof. The conductive material may be formed through a deposition process such as electroplating, electroless plating, or the like.

After the redistribution structure 108 is formed, the conductive pads 114 are formed over the redistribution structure 108, as shown in FIG. 2E in accordance with some embodiments. In some embodiments, the conductive pads 114 are physically connected to the redistribution layers 112 in the redistribution structure 108. In addition, the conductive pads 114 are electrically connected to the through insulating vias 104 and the conductive connectors 212 of the semiconductor dies 30 and 40 through the redistribution layers 112 in the redistribution structure 108 in accordance with some embodiments. In some embodiments, the conductive pads 114 are made of conductive material, such as W, Ru, Co, Cu, Ti, TiN, Ta, TaN, Mo, Ni, Al, other applicable conductive materials, or a combination thereof. In some embodiments, the conductive pads 114 and the redistribution layers 112 are made of different conductive materials.

Afterwards, the package components 10 and 20 are disposed over the redistribution structure 108, as shown in FIGS. 2F and 1B in accordance with some embodiments. More specifically, the package components 10 and 20 are bonded to the conductive pads 114 over the redistribution structure 108 through conductive connectors 116 in accordance with some embodiments. As described previously, the package components 10 and 20 may be disposed over the redistribution structure 108 with the layout shown in FIGS. 1A to 1C. In addition, the package components 10 are HBM dies and the package components 20 are SoC dies in accordance with some embodiments. Furthermore, the package components 10 and 20 include the conductive pads 118 electrically connected to the devices in the package components 10 and 20 in accordance with some embodiments. In some embodiments, the conductive pads 114 are made of conductive material, such as W, Ru, Co, Cu, Ti, TiN, Ta, TaN, Mo, Ni, Al, other applicable conductive materials, or a combination thereof.

In some embodiments, the conductive connectors 116 are bonded to the conductive pads 118 of the package components 10 and 20. In some embodiments, the conductive connectors 116 are solder balls, metal pillars, controlled collapse chip connection (C4) bumps, micro bumps, electroless nickel-electroless palladium-immersion gold technique (ENEPIG) formed bumps, or the like. In some embodiments, the conductive connectors 116 are micro bumps vertically sandwiched between the conductive pads 114 and 118. In some embodiments, the conductive connectors 116 are made of a conductive material such as solder, copper, aluminum, gold, nickel, silver, palladium, tin, the like, or a combination thereof. In some embodiments, the conductive connectors 116 are formed by initially forming a layer of solder through evaporation, electroplating, printing, solder transfer, ball placement, or the like, and a reflow process may be performed in order to shape the material into the desired bump shapes. In some embodiments, the conductive connectors 116 include metal pillars (such as a copper pillar) formed by sputtering, printing, electro plating, electroless plating, CVD, or the like. The metal pillars may be solder free and have substantially vertical sidewalls.

After the package components 10 and 20 are bonded to the redistribution structure 108, an underfill 120 is formed around the package components 10 and 20, as shown in FIG. 2G in accordance with some embodiments. More specifically, bottom surfaces and sidewalls of the package components 10 and 20 are surrounded and covered by the underfill 120 in accordance with some embodiments. In addition, the conductive pads 114 and 118 and the conductive connectors 116 are embedded in the underfill 120 in accordance with some embodiments. In some embodiments, the top surfaces of the package components 10 and 20 are not covered (i.e. exposed) by the underfill 120. In some embodiments, the upper portions of the sidewall surfaces of the package components 10 and 20 are not covered (i.e. exposed) by the underfill 120.

In some embodiments, the underfill 120 are made of a polymer, epoxy, molding underfill, or the like. The underfill 120 may be formed by a capillary flow process after the package components 10 and 20 are attached to the redistribution structure 108. After the underfill 120 is formed, a curing process may be performed in accordance with some embodiments. The curing process may include heating the underfill 120 to a predetermined temperature for a predetermined period of time, using an anneal process or other heating process. The curing process may also include an ultra-violet (UV) light exposure process, an infrared (IR) energy exposure process, combinations thereof, or a combination thereof with a heating process.

Next, an encapsulant 122 is formed around the underfill 120, as shown in FIG. 2H in accordance with some embodiments. More specifically, the package components 10 and 20 and the underfill 120 are covered and surrounded by the encapsulant 122 in accordance with some embodiments. In some embodiments, the encapsulant 122 includes an epoxy, an organic polymer, a polymer with or without a silica-based filler or glass filler added, or the like. In some embodiments, the encapsulant 122 includes a liquid molding compound (LMC) that is a gel type liquid when applied. The encapsulant 122 may also include a liquid or solid when applied. Alternatively, the encapsulant 122 include other insulating and/or encapsulating materials. The encapsulant 122 may be applied using a wafer level molding process. The encapsulant 122 may be molded using, for example, compressive molding, transfer molding, molded underfill (MUF), or other methods. In some embodiments, the encapsulant 122 and the underfill 120 are made of different materials. A curing process may be performed to the encapsulant 122. The curing process may include heating the encapsulant 122 to a predetermined temperature for a predetermined period of time, using an anneal process or other heating process. The curing process may also include an ultra-violet (UV) light exposure process, an infrared (IR) energy exposure process, combinations thereof, or a combination thereof with a heating process.

After the encapsulant 122 is formed, a planarization process is performed until the top surfaces of the package components 10 and 20 are exposed, as shown in FIG. 2I in accordance with some embodiments. The planarization process may be performed to remove excess portions of encapsulant 122 by using a mechanical grinding process, a chemical mechanical polishing (CMP) process, or the like. In some embodiments, the package components 10 and 20 are also slightly polished during the planarization process. After the planarization process, the top surfaces of the package components 10 and 20 are substantially level with the top surface of the encapsulant 122 in accordance with some embodiments.

Next, a carrier substrate 124 is attached to the encapsulant 122 and the package components 10 and 20, as shown in FIG. 2J in accordance with some embodiments. The carrier substrate 124 may be configured to provide structural support during the manufacturing processes of the package structure 100. In some embodiments, the carrier substrate 124 is made of a material such as silicon, polymer, polymer composite, metal foil, ceramic, glass, glass epoxy, beryllium oxide, tape, or other suitable material for structural support. In some embodiments, the carrier substrate 124 is a sapphire glass substrate. In some embodiments, the carrier substrate 102 and 124 are made of the same material but with different thicknesses.

After the carrier substrate 124 is attached to the encapsulant 122, the package structure is flipped upside down, and the carrier substrate 102 is removed, as shown in FIG. 2K in accordance with some embodiments. In some embodiments the carrier substrate 102 is removed by a carrier de-bonding process. The carrier de-bonding process may remove the carrier substrate 102 using any suitable process, such as etching, grinding, and mechanical peel off. In some embodiments, residues, such as adhesive, may remain on the exposed surfaces of the semiconductor dies 30 and 40 after the carrier substrate 102 is removed. Next, a cleaning process 126 is performed to clean the exposed surfaces of the semiconductor dies 30 and 40, as shown in FIG. 2L in accordance with some embodiments.

Afterwards, a heat spreader layer 130 is formed over the encapsulant 106, the through insulating vias 104, and the semiconductor dies 30 and 40, as shown in FIG. 2M in accordance with some embodiments. The heat spreader layer 130 may be configured to spread (e.g. dissipate) the heat generated from the semiconductor dies 30 and 40. In some embodiments, the heat spreader layer 130 is in direct contact with the substrate 202 of the semiconductor dies 30 and 40. In some embodiments, the heat spreader layer 130 and the interconnect structure 206 are at opposite sides of the substrate 202 of the semiconductor dies 30 and 40.

In some embodiments, the heat spreader layer 130 is a carbon-containing layer having a relatively high lateral thermal conductivity. In some embodiments, the thermal conductivity of the heat spreader layer 130 is greater than a thermal conductivity of the encapsulant 106. In some embodiments, the heat spreader layer 130 is made of graphene or diamond-like carbon. In some embodiments, the heat spreader layer 130 has a thermal conductivity in a range of about 1 W/m-K to about 1000 W/m-K. In some embodiments, the heat spreader layer 130 has a thickness in a range from about 10 μm to about 30 μm. The heat spreader layer 130 should be thick enough to provide enough heat conductivity but may not be too thick or the formation of the material layer may be difficult.

After the heat spreader layer 130 is formed, openings 132 are formed through the heat spreader layer 130, as shown in FIG. 2N in accordance with some embodiments. FIG. 2N-1 illustrates an enlarged cross-sectional view of the region R_2N shown in FIG. 2N in accordance with some embodiments. As shown in FIGS. 2N and 2N-1, the through insulating vias 104 and the conductive vias 204 in the semiconductors dies 30 and 40 are exposed by the openings 132 in accordance with some embodiments.

The openings 132 may be formed by forming a mask layer over the heat spreader layer 130, transferring the pattern of the mask layer onto the heat spreader layer 130 by performing an etching process, and removing the mask layer. In some embodiments, the exposed portions of the through insulating vias 104 and the conductive vias 204 are also slightly etched, so that the through insulating vias 104 and the conductive vias 204 have curved top surfaces exposed by the openings 132. In some embodiments, the heat spreader layer 130 has rounded corners and sloped sidewall surfaces at the openings 132.

After the openings 132 are formed, conductive features 134 are formed in the openings 132, as shown in FIG. 2O in accordance with some embodiments. FIGS. 2O-1 and 2O-2 illustrate enlarged cross-sectional views of the region R_20 shown in FIG. 2O in accordance with some embodiments.

More specifically, FIG. 2O-1 illustrates conductive features 134-1 formed in the openings 132 in accordance with some embodiments. The conductive features 134-1 may be formed by forming a conductive material in the openings 132 and over the heat spreader layer 130 and a performing a planarization process onto the conductive material until the top surface of the heat spreader layer 130 is exposed. The planarization process may be performed to remove excess portions of conductive material by using a mechanical grinding process, a chemical mechanical polishing (CMP) process, or the like. In some embodiments, the conductive material includes W, Ru, Co, Cu, Ti, TiN, Ta, TaN, Mo, Ni, Al, other applicable conductive materials, or a combination thereof. After the planarization process is performed, the top surfaces of the conductive features 134-1 are substantially level with the top surface of the heat spreader layer 130 in accordance with some embodiments. In some embodiments, at least one of the conductive features 134-1 has tip portions vertically overlapping the heat spreader layer 130 and the encapsulant 106. In some embodiments, at least one of the conductive features 134-1 has tip portions 134-1T vertically overlapping the heat spreader layer 130 and the semiconductor dies 30 or 40.

FIG. 2O-2 illustrate conductive features 134-2 formed in the openings 132 in accordance with some embodiments. The conductive features 134-2 may be formed by selectively depositing a conductive material in the openings 132 until the top surface of the conductive material is substantially level with the top surface of the heat spreader layer 130. In some embodiments, the conductive material includes W, Ru, Co, Cu, Ti, TiN, Ta, TaN, Mo, Ni, Al, other applicable conductive materials, or a combination thereof. As shown in FIG. 2O-2, each of the conductive features 134-2 has a convex top surface. In some embodiments, the middle portion of each of the conductive features 134-2 is thicker than its edge portion.

As shown in both FIGS. 2O-1 and 2O-2, since the heat spreader layer 130 has slope sidewall surfaces at the openings 132, the conductive features 134, including the conductive features 134-1 and 134-2, have slope sidewall surface in direct contact with the heat spreader layer 130. In addition, a top surface of each of the conductive features 134 is wider than its bottom surface (e.g. in X direction) in accordance with some embodiments. That is, the upper portion of the conductive features 134 is wider than the bottom portion of the conductive features 134 (e.g. in X direction) in accordance with some embodiments.

After the conductive features 134 are formed, a redistribution structure 140 is formed over the heat spreader layer 130, as shown in FIG. 2P in accordance with some embodiments. In some embodiments, the redistribution structure 140 includes multiple insulating layers 142 and redistribution layers (RDLs) 144 (labeled in FIG. 2P-1), and the redistribution layers 144 are electrically connected to the conductive features 134 in the heat spreader layer 130. The redistribution layers 144 may be seen as a fan-out structure. The numbers of the insulating layers 142 and redistribution layers 144 shown in FIG. 2P are merely an example and are not intended to be limited. For example, the numbers of the insulating layers 142 and redistribution layers 144 may be in a range from about 1 to about 15.

In some embodiments, the thermal conductivity of the heat spreader layer 130 is greater than a thermal conductivity of the insulating layers 142. In some embodiments, the insulating layer 142 are made of one or more suitable dielectric materials such as an oxide (e.g., silicon oxide), a nitride (e.g., silicon nitride), a polymer material, a polyimide material, a low-k dielectric material, a molding material (e.g., an EMC or the like), another dielectric material, or a combination thereof. The insulation layers 142 may be formed by a process such as spin-coating, lamination, CVD, the like, or a combination thereof. In some embodiments, the redistribution layers 144 are made of a conductive material such as copper, titanium, tungsten, aluminum, another metal, or a combination thereof. The conductive material may be formed through a deposition process such as electroplating, electroless plating, or the like.

After the redistribution structure 140 is formed, conductive connectors 146 are formed over the redistribution structure 140, and the package structure 100 is formed, as show in FIG. 2P in accordance with some embodiments. The conductive connectors 146 may include bonding pads, microbumps, copper pillars, copper layers, nickel layers, lead free layers, electroless nickel electroless palladium immersion gold (ENEPIG) layers, Sn/Ag layers, Sn/Pb layers, or the like. In some embodiments, the conductive connectors 146 include conductive pillars 148 and solder balls 150 formed over the conductive pillars 148. In some embodiments, the conductive connectors 146 are electrically connected to the redistribution layers 144 in the redistribution structure 140.

FIGS. 2P-1 and 2P-2 illustrate enlarged cross-sectional views of the region R_2P shown in FIG. 2P in accordance with some embodiments. More specifically, FIG. 2P-1 illustrates the package structure 100 including the conductive features 134-1 as shown in FIG. 2O-1 in accordance with some embodiments. In some embodiments, the bottom surface of the bottommost one of the insulating layers 142 is substantially level with the top surface of the conductive features 134-1.

FIG. 2P-2 illustrates the package structure 100 including the conductive features 134-2 as shown in FIG. 2O-2 in accordance with some embodiments. In some embodiments, the redistribution layers 144 over the conductive features 134-2 have concave bottom surfaces in direct contact with the convex top surfaces of the conductive features 134-2. In some embodiments, the bottom surface of the bottommost one of the insulating layers 142 is not flat. In some embodiments, the bottommost one of the insulating layers 142 has a protruding portions laterally sandwiched (e.g. in X direction) between the conductive features 134-2 and the heat spreader layer 130. In some embodiments, the bottommost portion of the bottommost one of the insulating layers 142 is lower than the top most portion of the top surface of the heat spreader layer 130.

In the package structure 100, the semiconductor dies 30 and 40 may generate relatively greater heat during the operation, and the heat may even impact the performance of the package components 10 and 20. Therefore, the heat spreader layer 130 with a high thermal conductivity is formed over the semiconductor dies 30 and 40, so that the heat generated by the semiconductor dies 30 and 40 may be spread laterally. Accordingly, the temperature of the package structure 100, especially at the hot spots around the semiconductor dies 30 and 40, may be reduced (e.g. about 8° C. lower at the semiconductor dies 30 and 40, about 10° C. lower at the package component 10, and about 3° C. lower at the package component 20), and the performance of the package structure 100 may therefore be improved.

In some embodiments, the package structure 100 includes the redistribution structure 108, and all the package components 10 and 20 shown in FIGS. 1A to 1C are positioned over a first side of the redistribution structure 108. In addition, all the semiconductor dies 30 and 40 shown in FIGS. 1A to 1C are positioned over a second side of the redistribution structure 108, as shown in FIG. 2P in accordance with some embodiments. In addition, the package components 10 and 20 are spaced apart from each other in both X and Y direction, and the semiconductor dies 30 and 40 are spaced apart from each other in both X and Y direction as shown in FIGS. 1A to 1C in accordance with some embodiments. As described previously, the semiconductor dies 30 and 40 may be configured to electrically connect the package components 10 and 20. Therefore, each of the semiconductor die 30 partially overlaps both the package components 10 and 20 (i.e. in the projection area of the semiconductor dies 30).

Furthermore, the heat spreader layer 130 is formed over the semiconductor dies 30 and 40 and is vertically sandwiched between the semiconductor dies 30 and 40 and the redistribution structure 140 in accordance with some embodiments. The conductive features 134, including the conductive features 134-1 and 134-2, are formed through the heat spreader layer 130, so that the through insulating vias 104 and the conductive vias 204 of the semiconductor dies 30 and 40 are electrically connected to the redistribution structure 140 through the conductive features 134 in accordance with some embodiments. In some embodiments, the projection area of the heat spreader layer 130 is greater than the projection areas of the semiconductor dies 30 and 40 and the projection areas of the package components 10 and 20. In some embodiments, the projection areas of the semiconductor dies 30 and 40 and the projection areas of the package components 10 and 20 are within the projection area of the heat spreader layer 130.

FIG. 3 illustrates a cross-sectional view of a package structure 100′ in accordance with some embodiments. The package structure 100′ may be similar to the package structure 100 described previously, except conductive features 134′a, 134′b, and 134′c formed in the heat spreader layer 130 are wider than the through insulating vias 104 and the conductive vias 204 in the semiconductor dies 30 and 40 in accordance with some embodiments. That is, the package structure 100′ may also have the layout shown in FIGS. 1A to 1C described previously. Processes and materials for forming the package structure 100′ may be similar to, or the same as, those for forming the package structure 100 described previously and are not repeated herein.

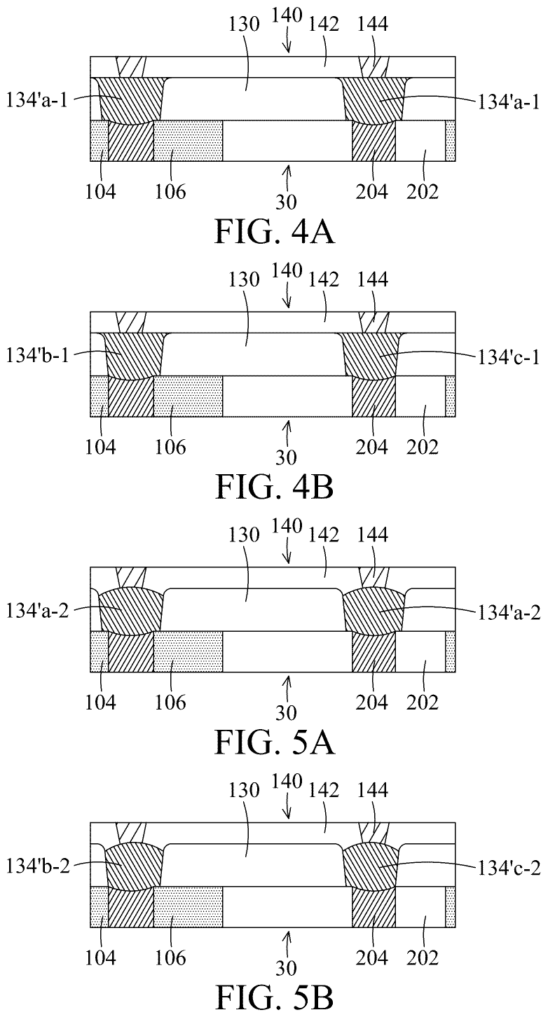

FIG. 4A illustrates an enlarged cross-sectional view of the region R_3a shown in FIG. 3 in accordance with some embodiments. As shown in FIG. 4A, conductive features 134′a-1 are formed in the heat spreader layer 130 and are electrically connected to the through insulating vias 104 and the conductive vias 204 in the semiconductor dies 30 and 40 in accordance with some embodiments. The structures and materials of the conductive features 134′a-1 are substantially similar to, or the same as, those of the conductive features 134-1 shown in FIG. 2P-1, except the conductive features 134′a-1 are relatively wider.

In some embodiments, at least one of the conductive features 134′a-1 is wider than one of the through insulating via 104 in X direction. In some embodiments, at least one of the conductive features 134′a-1 is wider than one of the through via 204 in X direction. In some embodiments, the conductive feature 134′a-1 laterally protrudes from the opposite sidewall surfaces of the through insulating via 104 underneath the conductive feature 134′a-1. In some embodiments, the bottom surface of the conductive feature 134′a-1 is in direct contact with the top surface of the encapsulant 106. In some embodiments, the conductive feature 134′a-1 laterally protrudes from the opposite sidewall surface of the conductive via 204 underneath the conductive feature 134′a-1. In some embodiments, the bottom surface of the conductive feature 134′a-1 is in direct contact with the top surface of the substrate 202 of the semiconductor dies 30 and 40.

FIG. 4B illustrates an enlarged cross-sectional view of the region R_3b shown in FIG. 3 in accordance with some embodiments. As shown in FIG. 4B, conductive features 134′b-1 and 134′c-1 are formed in the heat spreader layer 130 and are electrically connected to the through insulating vias 104 and the conductive vias 204 in the semiconductor dies 30 and 40, respectively, in accordance with some embodiments. The structures and materials of the conductive features 134′b-1 and 134′c-1 are substantially similar to, or the same as, those of the conductive features 134-1 shown in FIG. 2P-1, except the conductive features 134′b-1 and 134′c-1 are relatively wider. In some embodiments, at least one of the conductive features 134′b-1 laterally protrudes from one of the sidewall surfaces of the through insulating via 104 underneath the conductive feature 134′b-1. In some embodiments, the bottom surface of the conductive feature 134′b-1 is in direct contact with the top surface of the encapsulant 106. In some embodiments, the conductive feature 134′c-1 laterally protrudes from one of the sidewall surfaces of the conductive via 204 underneath the conductive feature 134′c-1. In some embodiments, the bottom surface of the conductive feature 134′c-1 is in direct contact with the top surface of the substrate 202 of the semiconductor dies 30 and 40.

FIG. 5A illustrates an enlarged cross-sectional view of the region R_3a shown in FIG. 3 in accordance with some other embodiments. As shown in FIG. 5A, conductive features 134′a-2 are formed in the heat spreader layer 130 and are electrically connected to the through insulating vias 104 and the conductive vias 204 in the semiconductor dies 30 and 40 in accordance with some embodiments. The structures and materials of the conductive features 134′a-2 are substantially similar to, or the same as, those of the conductive features 134-2 shown in FIG. 2P-2, except the conductive features 134′a-2 are wider. The spatial relationship of the conductive features 134′a-2 and the neighboring elements are the same as that of the conductive features 134′a-1 shown in FIG. 4A and the shape of the conductive features 134′a-2 are the same as that of the conductive features 134-2 shown in FIG. 2P-2 in accordance with some embodiments. Therefore, detail of the conductive features 134′a-2 are not repeated herein.

FIG. 5B illustrates an enlarged cross-sectional view of the region R_3b shown in FIG. 3 in accordance with some other embodiments. As shown in FIG. 5B, conductive features 134′b-2 and 134′c-2 are formed in the heat spreader layer 130 and are electrically connected to the through insulating vias 104 and the conductive vias 204 in the semiconductor dies 30 and 40, respectively, in accordance with some embodiments. The structures and materials of the conductive features 134′b-2 and 134′c-2 are substantially similar to, or the same as, those of the conductive features 134-2 shown in FIG. 2P-2, except the conductive features 134′b-2 and 134′c-2 are relatively wider. The spatial relationship of the conductive features 134′b-2 and 134′c-2 and the neighboring elements are the same as that of the conductive features 134′b-1 and 134′c-1 shown in FIG. 4B and the shape of the conductive features 134′b-2 and 134′c-2 are the same as that of the conductive features 134-2 shown in FIG. 2P-2 in accordance with some embodiments. Therefore, detail of the conductive features 134′b-2 and 134′c-2 are not repeated herein.

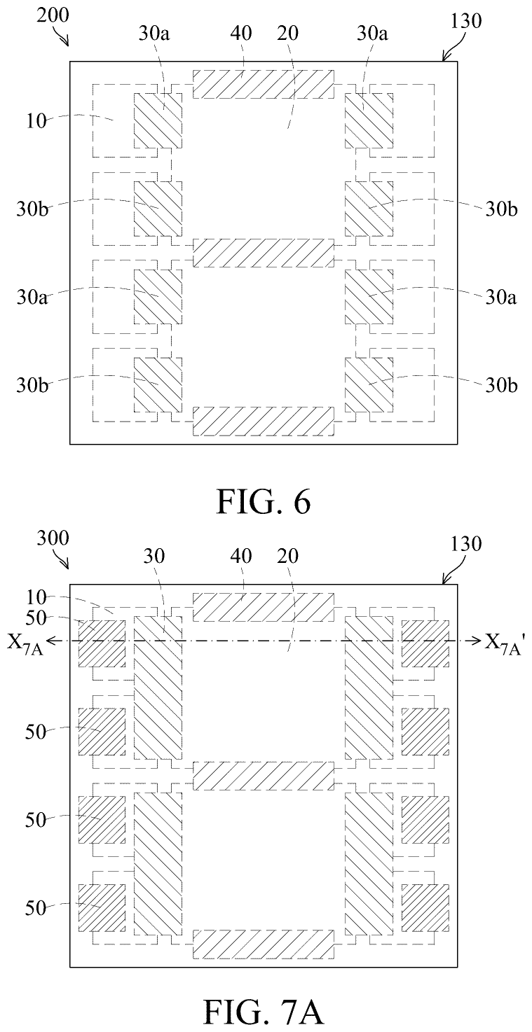

FIG. 6 illustrates a diagrammatic top view of a package structure 200 in accordance with some embodiments. The package structure 200 may be similar to the package structure 100 described previously, except the size of semiconductor dies are different with those in the package structure 100 in accordance with some embodiments. Processes and materials for forming the package structure 200 may be similar to, or the same as, those for forming the package structure 100 described previously and are not repeated herein.

As shown in FIG. 6, the package structure 200 includes the package components 10 and 20 and the semiconductor dies 40, but the semiconductor dies 30 are replaced by semiconductor dies 30a and 30b in accordance with some embodiments. More specifically, each of the semiconductor dies 30a and 30b are configured to connect the electrical signals between one of the package components 10 and one of the package component 20 in accordance with some embodiments. The function and formation of the semiconductor dies 30a and 30b may be the same as those of the semiconductor dies 30 and therefore are not repeated herein.

Similar to the package structure 100, the heat spreader layer 130 in the package structure 200 is formed over the semiconductor dies 30a, 30b, and 40, so that the heat generate by the semiconductor dies 30a, 30b, and 40 during the operation can be dissipated and the temperature of the device may be reduced. In some embodiments, the semiconductor dies 30a, 30b, and 40 are completely covered by (e.g. in the projection area of) the heat spreader layer 130. In some embodiments, the width of the heat spreader layer 130 is greater than the width of each of the semiconductor dies 30a, 30b, and 40 in both X direction and Y direction.

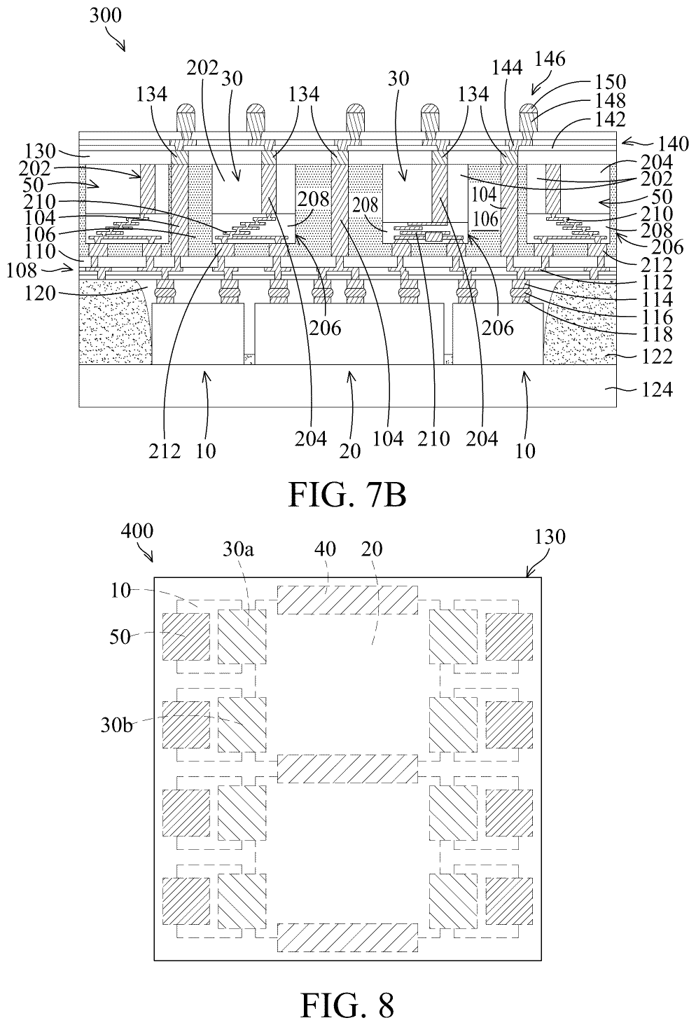

FIG. 7A illustrates a diagrammatic top view of a package structure 300 in accordance with some embodiments. FIG. 7B illustrates a cross-sectional view of the package structure 300 shown along line X_{7A}-X_{7A}′ in FIG. 7A in accordance with some embodiments. The package structure 300 may be similar to the package structure 100 described previously, except semiconductor dies 50 are disposed along with the semiconductor dies 30 and 40 in accordance with some embodiments. Processes and materials for forming the package structure 300 may be similar to, or the same as, those for forming the package structure 100 described previously and are not repeated herein.

As shown in FIG. 7A, the package structure 300 includes the package components 10 and 20 and the semiconductor dies 30 and 40, and additional semiconductor dies 50 are also disposed in the package structure 300 in accordance with some embodiments. The semiconductor dies 50 may be configured to control the power of the package components 10. More specifically, the semiconductor dies 30, 40, and 50 are disposed over the carrier substrate 102, and the processes shown in FIGS. 2C to 2P are performed to form the package structure 300, as shown in FIG. 7B in accordance with some embodiments. In some embodiments, each of the semiconductor dies 50 partially overlaps one of the package components 10.

Similar to the package structure 100, the heat spreader layer 130 in the package structure 300 is formed over the semiconductor dies 30, 40, and 50, so that the heat generate by the semiconductor dies 30, 40, and 50 during the operation can be dissipated and the temperature of the device may be reduced. In some embodiments, the semiconductor dies 30, 40, and 50 are completely covered by (i.e. in the projection area of) the heat spreader layer 130. In some embodiments, the width of the heat spreader layer 130 is greater than the width of each of the semiconductor dies 30, 40, and 50 in both X direction and Y direction, as shown in FIG. 7A.

FIG. 8 illustrates a diagrammatic top view of a package structure 400 in accordance with some embodiments. The package structure 400 may be similar to the package structure 200 described previously, except the semiconductor dies 50 are also disposed in accordance with some embodiments. Processes and materials for forming the package structure 400 may be similar to, or the same as, those for forming the package structures 100, 200, and 300 described previously and are not repeated herein.

As shown in FIG. 8, the package structure 400 includes the package components 10 and 20 and the semiconductor dies 30a, 30b, 40, and 50 in accordance with some embodiments. Similar to the package structure 200, the heat spreader layer 130 in the package structure 400 is formed over the semiconductor dies 30a, 30b, 40, and 50, so that the heat generate by the semiconductor dies 30a, 30b, 40, and 50 during the operation can be dissipated and the temperature of the device may be reduced. In some embodiments, the semiconductor dies 30a, 30b, 40, and 50 are completely covered by (i.e. in the projection area of) the heat spreader layer 130. In some embodiments, the width of the heat spreader layer 130 is greater than the width of each of the semiconductor dies 30a, 30b, 40, and 50 in both X direction and Y direction, as shown in FIG. 8.

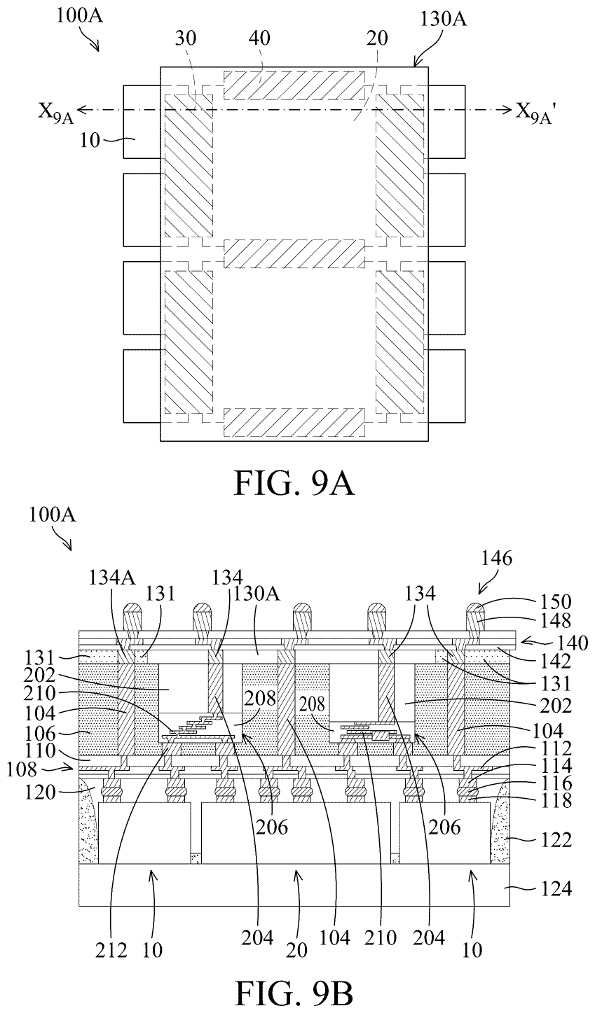

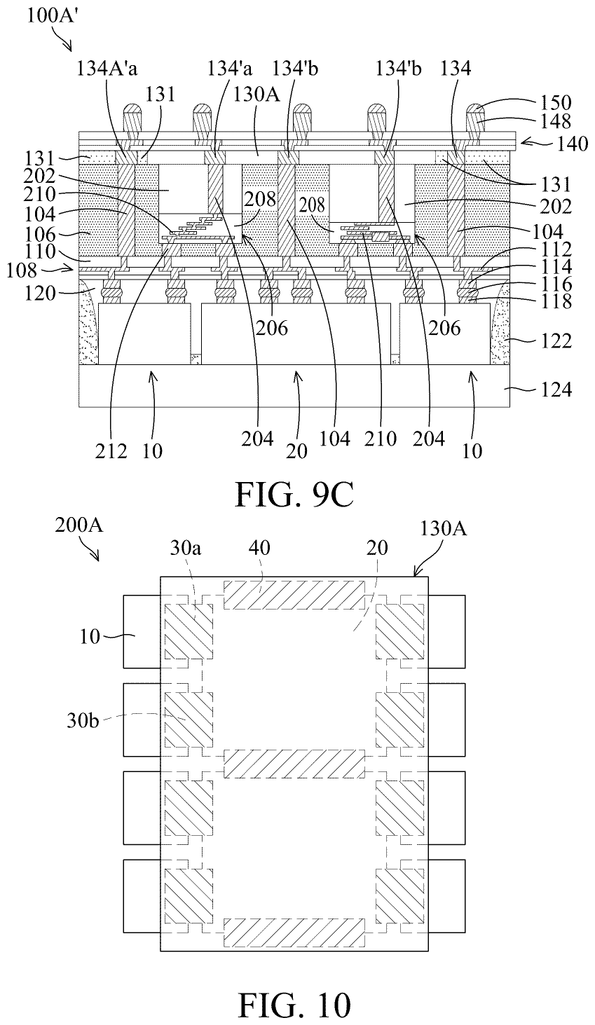

FIG. 9A illustrates a diagrammatic top view of a package structure 100A in accordance with some embodiments. FIG. 9B illustrates a cross-sectional view of the package structure 100A along line X_{9A}-X_{9A}′ in accordance with some embodiments. The package structure 100A may be similar to the package structure 100 described previously, except the size of its heat spreader layer is different in accordance with some embodiments. Processes and materials for forming the package structure 100A may be similar to, or the same as, those for forming the package structure 100 described previously and are not repeated herein.

As shown in FIG. 9A, the package structure 100A includes the package components 10 and 20 and the semiconductor dies 30 and 40 in accordance with some embodiments. In addition, a heat spreader layer 130A is formed over the semiconductor dies 30 and 40, so that the heat generate by the semiconductor dies 30 and 40 during the operation can be dissipated and the temperature of the device may be reduced. In some embodiments, the semiconductor dies 30 and 40 are completely covered by (i.e. in the projection area of) the heat spreader layer 130A. In some embodiments, the width of the heat spreader layer 130A is greater than the width of each of the semiconductor dies 30 and 40 in both X direction and Y direction. In some embodiments, the package components 20 are also completely covered by (i.e. in the projection area of) the heat spreader layer 130A. In some embodiments, the package components 10 are partially covered by (i.e. partially outside the projection area of) the heat spreader layer 130A.

More specifically, the processes shown in FIGS. 2A to 2L are performed, and a dielectric layer 131 is formed over encapsulant 106 and the heat spreader layer 130A is positioned in the dielectric layer 131, as shown in FIG. 9B in accordance with some embodiments. In addition, conductive features 134A are formed in the dielectric layer 131 in accordance with some embodiments.

In some embodiments, the formation of the dielectric layer 131 and the heat spreader layer 130A includes forming the dielectric layer 131 covering the encapsulant 106, forming an opening in the dielectric layer 131, and forming the heat spreader layer 130A in the opening. In some other embodiments, the formation of the dielectric layer 131 and the heat spreader layer 130A includes forming the heat spreader layer 130A covering the encapsulant 106, patterning the heat spreader layer 130A, and forming the dielectric layer 131 around the heat spreader layer 130A.

In some embodiments, dielectric layer 131 is made of a dielectric material having a k value lower than 7. In some embodiments, the dielectric layer 131 is made of SiO₂, SiN, SiCN, SiOC, SiOCN, or the like. The dielectric layer 131 may be formed by chemical vapor deposition (CVD), physical vapor deposition, (PVD), atomic layer deposition (ALD), or other applicable processes. The processes and materials for forming the heat spreader layer 130A and the conductive features 134A are substantially similar to, or the same as, those for forming the heat spreader layer 130 and the conductive features 134 described previously and are not repeated herein.

After the dielectric layer 131 and the heat spreader layer 130A are formed, the processes shown in FIG. 2P are performed to form the package structure 100A, as shown in FIG. 9B in accordance with some embodiments. Although not clearly show in FIG. 9B, the conductive features 134A of the package structure 100A may have the structures similar to those shown in FIG. 2P-1 or 2P-2 in accordance with some embodiments.

FIG. 9C illustrates a cross-sectional view of a package structure 100A′ in accordance with some embodiments. The package structure 100A′ may be similar to the package structure 100A described previously, except its conductive features are wider than those in the package structure 100A in accordance with some embodiments. Processes and materials for forming the package structure 100A′ may be similar to, or the same as, those for forming the package structures 100 and 100A described previously and are not repeated herein. In addition, the package structure 100A′ also has the layout shown in FIG. 9A in accordance with some embodiments.

More specifically, the heat spreader layer 130A is formed in the dielectric layer 131, and the conductive features 134′a and 134′b (e.g. the same as the conductive features 134′a and 134′b shown in FIG. 3) are formed in the heat spreader layer 130A in accordance with some embodiments. In addition, the package structure 100A′ further includes a conductive feature 134A′a, and the conductive feature 134A′a is substantially similar to, or the same as, the conductive feature 134′a shown in FIG. 3, except the conductive feature 134A′a is formed in the dielectric layer 131 in accordance with some embodiments. Although not clearly show in FIG. 9C, the conductive features 134A′a of the package structure 100A′ may have the structures similar to those shown in FIG. 4A or 5A.

FIG. 10 illustrates a diagrammatic top view of a package structure 200A in accordance with some embodiments. The package structure 200A may be similar to the package structure 200 described previously, except the size of its heat spreader layer is different in accordance with some embodiments. Processes and materials for forming the package structure 200A may be similar to, or the same as, those for forming the package structure 200 described previously and are not repeated herein.

As shown in FIG. 10, the package structure 200A includes the package components 10 and 20 and the semiconductor dies 30a, 30b, and 40 in accordance with some embodiments. In addition, the heat spreader layer 130A is formed over the semiconductor dies 30a, 30b, and 40, so that the heat generate by the semiconductor dies 30a, 30b, and 40 during the operation can be dissipated and the temperature of the device may be reduced. In some embodiments, the semiconductor dies 30a, 30b, and 40 are completely covered by (i.e. in the projection area of) the heat spreader layer 130A. In some embodiments, the width of the heat spreader layer 130A is greater than the width of each of the semiconductor dies 30a, 30b, and 40 in both X direction and Y direction. In some embodiments, the package components 20 are also completely covered (i.e. in the projection area of) by the heat spreader layer 130A. In some embodiments, the package components 10 are partially covered by (i.e. partially outside the projection area of) the heat spreader layer 130A.

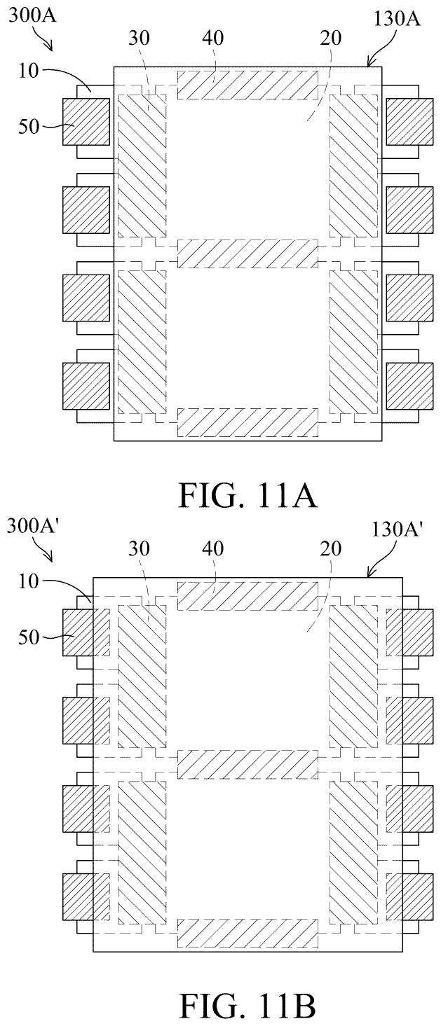

FIG. 11A illustrates a diagrammatic top view of a package structure 300A in accordance with some embodiments. The package structure 300A may be similar to the package structure 300 described previously, except the size of its heat spreader layer is different in accordance with some embodiments. Processes and materials for forming the package structure 300A may be similar to, or the same as, those for forming the package structure 300 described previously and are not repeated herein.

As shown in FIG. 11A, the package structure 300A includes the package components 10 and 20 and the semiconductor dies 30, 40, and 50 in accordance with some embodiments. In addition, the heat spreader layer 130A is formed over the semiconductor dies 30 and 40, so that the heat generate by the semiconductor dies 30 and 40 during the operation can be dissipated and the temperature of the device may be reduced. On the other hand, the semiconductor dies 50 are not covered by (i.e. completely outside the projection area of) the heat spreader layer 130A, since the heat generated by the semiconductor dies 50 may be less than heat generated by the semiconductor dies 30 and 40. In some embodiments, the semiconductor dies 30 and 40 are completely covered by the heat spreader layer 130A, while the semiconductor dies 50 are not covered by the heat spreader layer 130A.

FIG. 11B illustrates a diagrammatic top view of a package structure 300A′ in accordance with some embodiments. The package structure 300A′ may be similar to the package structure 300 described previously, except the size of its heat spreader layer is different in accordance with some embodiments. Processes and materials for forming the package structure 300A′ may be similar to, or the same as, those for forming the package structure 300 described previously and are not repeated herein.

As shown in FIG. 11B, the package structure 300A′ includes the package components 10 and 20 and the semiconductor dies 30, 40, and 50 in accordance with some embodiments. In addition, a heat spreader layer 130A′ is formed over the semiconductor dies 30 and 40. In some embodiments, the semiconductor dies 30 and 40 are completely covered by (i.e. in the projection area of) the heat spreader layer 130A′, while the semiconductor dies 50 are partially covered by (i.e. partially outside the projection area of) the heat spreader layer 130A′. Processes and materials for forming the heat spreader layer 130A′ may be similar to, or the same as, those for forming heat spreader layer 130A described previously and are not repeated herein.

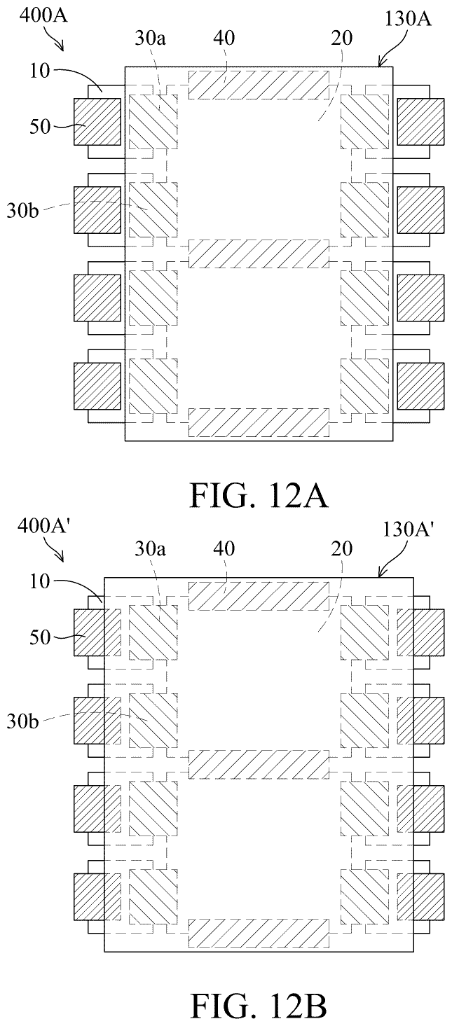

FIG. 12A illustrates a diagrammatic top view of a package structure 400A in accordance with some embodiments. The package structure 400A may be similar to the package structure 400 described previously, except the size of its heat spreader layer is different in accordance with some embodiments. Processes and materials for forming the package structure 400A may be similar to, or the same as, those for forming the package structure 300 described previously and are not repeated herein.

As shown in FIG. 12A, the package structure 400A includes the package components 10 and 20 and the semiconductor dies 30a, 30b, 40, and 50 in accordance with some embodiments. In addition, the heat spreader layer 130A is formed over the semiconductor dies 30a, 30b, and 40, so that the heat generated by the semiconductor dies 30a, 30b, and 40 can be dissipated, but the semiconductor dies 50 are not covered by the heat spreader layer 130A since the heat generated by the semiconductor dies 50 may be less than heat generated by the semiconductor dies 30a, 30b, and 40 can be dissipated. In some embodiments, the semiconductor dies 30a, 30b, and 40 are completely covered by (i.e. in the projection area of) the heat spreader layer 130A, while the semiconductor dies 50 are not covered by (i.e. outside the projection area of) the heat spreader layer 130A.

FIG. 12B illustrates a diagrammatic top view of a package structure 400A′ in accordance with some embodiments. The package structure 400A′ may be similar to the package structure 400 described previously, except the size of its heat spreader layer is different in accordance with some embodiments. Processes and materials for forming the package structure 400A′ may be similar to, or the same as, those for forming the package structure 400 described previously and are not repeated herein.

As shown in FIG. 12B, the package structure 400A′ includes the package components 10 and 20 and the semiconductor dies 30a, 30b, 40, and 50 in accordance with some embodiments. In addition, the heat spreader layer 130A′ is formed over the semiconductor dies 30a, 30b, and 40, and the semiconductor dies 50 are not fully covered by the heat spreader layer 130A′. In some embodiments, the semiconductor dies 30a, 30b, and 40 are completely covered by (i.e. in the projection area of) the heat spreader layer 130A′, while the semiconductor dies 50 are partially covered by (i.e. partially outside the projection area of) the heat spreader layer 130A′.

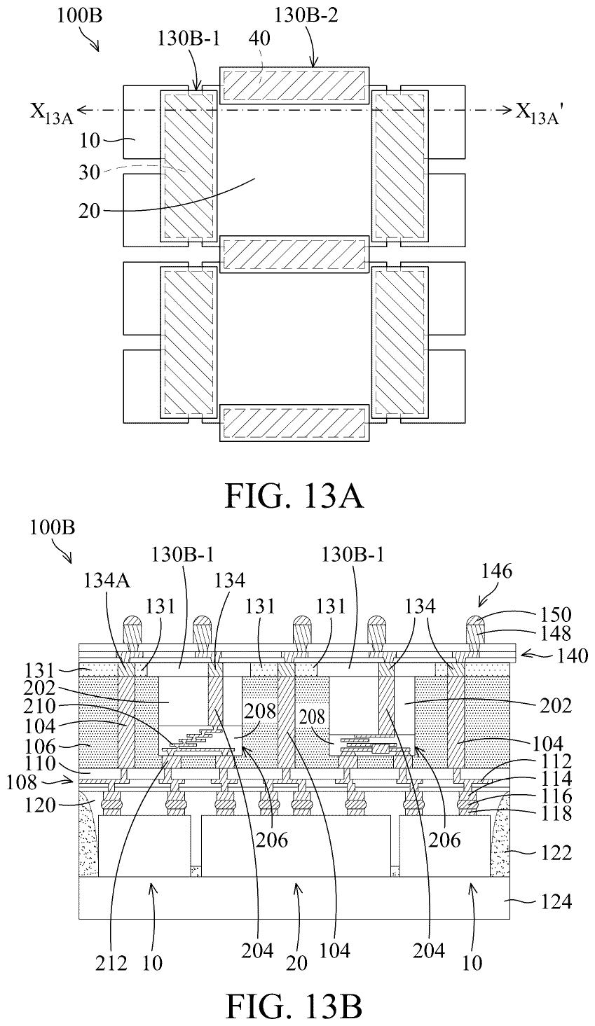

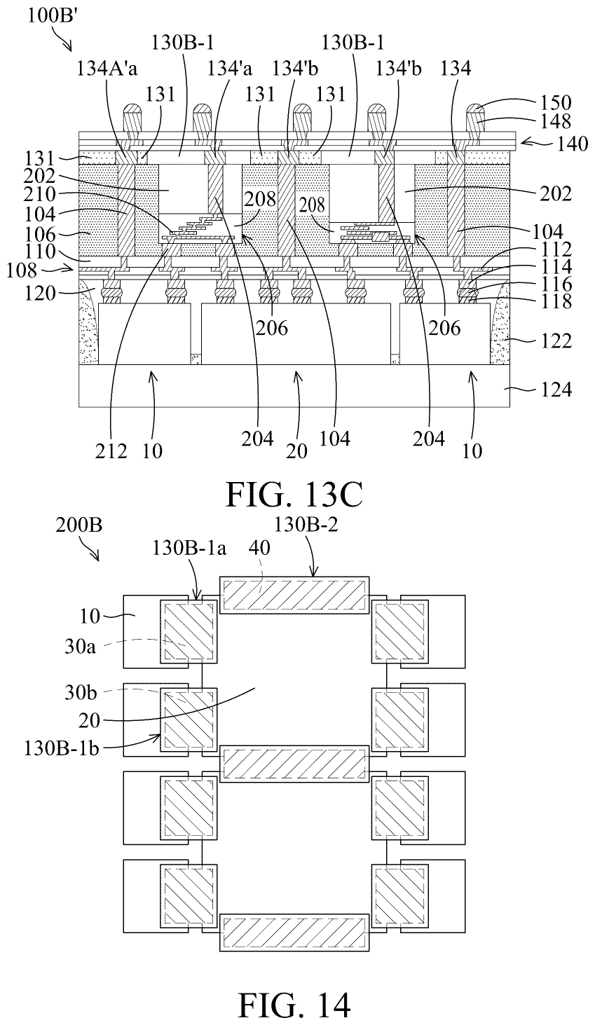

FIG. 13A illustrates a diagrammatic top view of a package structure 100B in accordance with some embodiments. FIG. 13B illustrates a cross-sectional view of the package structure 100B along line X_{13A}-X_{13A}′ in accordance with some embodiments. The package structure 100B may be similar to the package structure 100 described previously, except the size of its heat spreader layer is different in accordance with some embodiments. Processes and materials for forming the package structure 100B may be similar to, or the same as, those for forming the package structures 100 and 100A described previously and are not repeated herein.

As shown in FIG. 13A, the package structure 100B includes the package components 10 and 20 and the semiconductor dies 30 and 40 in accordance with some embodiments. In addition, heat spreader layers 130B-1 and 130B-2 are formed over and slightly larger than the semiconductor dies 30 and 40, respectively, so that the heat generate by the semiconductor dies 30 and 40 during the operation can be dissipated and the temperature of the device may be reduced. In some embodiments, the semiconductor dies 30 and 40 are completely covered by (i.e. in the projection areas of) the heat spreader layers 130B-1 and 130B-2. In some embodiments, the width of the heat spreader layers 130B-1 and 130B-2 are greater than the width of each of the semiconductor dies 30 and 40, respectively, in both X direction and Y direction. In some embodiments, the package components 10 are partially covered by the heat spreader layer 130B-1. In some embodiments, the package components 20 are partially covered by the heat spreader layers 130B-1 and 130B-2.

The processes for forming the heat spreader layers 130B-1 and 130B-2 may be similar to, or the same as, the processes for forming the heat spreader layer 130A described previously, except the heat spreader layers 130B-1 and 130B-2 are mainly formed over the semiconductor dies 30 and 40, respectively. In some embodiments, the heat spreader layers 130B-1 and 130B-2 are separated from each other in both X direction and Y direction in the top view shown in FIG. 13A. Although not clearly show in FIG. 13B, the conductive features 134A of the package structure 100B may have the structures similar to those shown in FIG. 2P-1 or 2P-2.

FIG. 13C illustrates a cross-sectional view of a package structure 100B′ in accordance with some embodiments. The package structure 100B′ may be similar to the package structure 100B described previously, except its conductive features are wider than those in the package structure 100B in accordance with some embodiments. Processes and materials for forming the package structure 100B′ may be similar to, or the same as, those for forming the package structures 100B described previously and are not repeated herein. In addition, the package structure 100B′ also has the layout shown in FIG. 13A in accordance with some embodiments. More specifically, the heat spreader layers 130B-1 and 130B-2 are formed in the dielectric layer 131, and the conductive features 134′a and 134′b are formed in the heat spreader layer 130B-1 and 130B-2 in accordance with some embodiments. Furthermore, the middle portions of the package components 20 are not covered by any of the heat spreader layers 130B-1 and 130B-2 in accordance with some embodiments.

FIG. 14 illustrates a diagrammatic top view of a package structure 200B in accordance with some embodiments. The package structure 200B may be similar to the package structure 200A described previously, except the size of its heat spreader layer is different in accordance with some embodiments. Processes and materials for forming the package structure 200B may be similar to, or the same as, those for forming the package structures 200 and 200A described previously and are not repeated herein.

As shown in FIG. 14, heat spreader layers 130B-1a, 130B-1b, and 130B-2 are formed over and slightly larger than the semiconductor dies 30a, 30b, and 40, respectively, in accordance with some embodiments. The processes for forming the heat spreader layers 130B-1a, 130B-1b, and 130B-2 may be similar to, or the same as, the processes for forming the heat spreader layer 130A described previously, except the heat spreader layers 130B-1a, 130B-1b, and 130B-2 are mainly formed over the semiconductor dies 30a, 30b, and 40, respectively. In some embodiments, the heat spreader layers 130B-1a, 130B-1b, and 130B-2 are separated from each other in the top view as shown in FIG. 14. Furthermore, the middle portions of the package components 20 are not covered by any of the heat spreader layers 130B-1a, 130B-1b, and 130B-2 in accordance with some embodiments.

FIG. 15 illustrates a diagrammatic top view of a package structure 300B in accordance with some embodiments. The package structure 300B may be similar to the package structure 300A described previously, except the size of its heat spreader layer is different in accordance with some embodiments. Processes and materials for forming the package structure 300B may be similar to, or the same as, those for forming the package structures 300 and 300A described previously and are not repeated herein.

As shown in FIG. 15, heat spreader layers 130B-1, 130B-2, and 130B-3 are formed over the semiconductor dies 30, 40, and 50, respectively in accordance with some embodiments. The processes for forming the heat spreader layers 130B-1, 130B-2, and 130B-3 may be similar to, or the same as, the processes for forming the heat spreader layer 130A described previously, except the heat spreader layers 130B-1, 130B-2, and 130B-3 are mainly formed over and slightly larger than the semiconductor dies 30, 40, and 50, respectively. In some embodiments, the heat spreader layers 130B-1, 130B-2, and 130B-3 are separated from each other in the top view as shown in FIG. 15. Furthermore, the middle portions of the package components 20 are not covered by any of the heat spreader layers 130B-1, 130B-2, and 130B-3 in accordance with some embodiments.

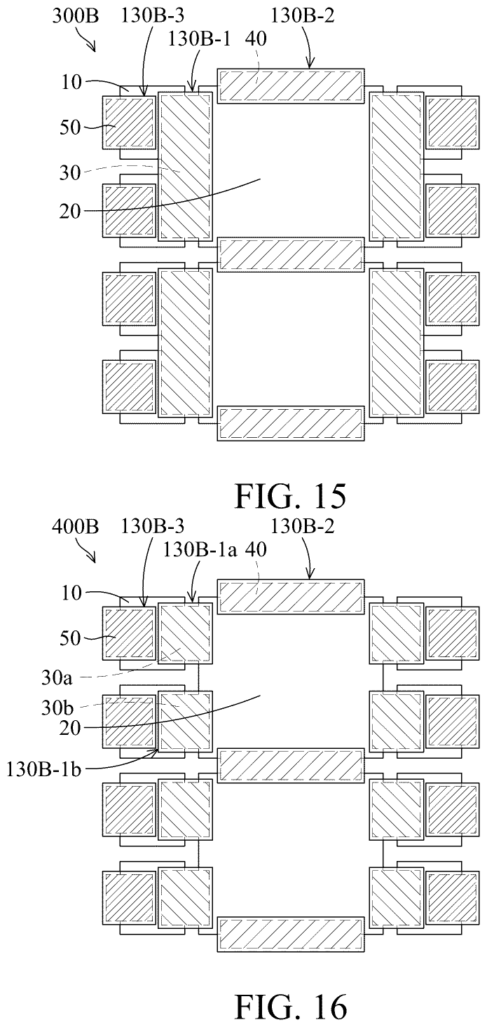

FIG. 16 illustrates a diagrammatic top view of a package structure 400B in accordance with some embodiments. The package structure 400B may be similar to the package structure 400A described previously, except the size of its heat spreader layer is different in accordance with some embodiments. Processes and materials for forming the package structure 400B may be similar to, or the same as, those for forming the package structures 400 and 400A described previously and are not repeated herein.

As shown in FIG. 16, heat spreader layers 130B-1a, 130B-1b, 130B-2, and 130B-3 are formed over the semiconductor dies 30a, 30b, 40, and 50, respectively in accordance with some embodiments. The processes for forming the heat spreader layers 130B-1a, 130B-1b, 130B-2, and 130B-3 may be similar to, or the same as, the processes for forming the heat spreader layer 130A described previously, except the heat spreader layers 130B-1a, 130B-1b, 130B-2, and 130B-3 are mainly formed over and slightly larger than the semiconductor dies 30a, 30b, 40, and 50, respectively. In some embodiments, the heat spreader layers 130B-1a, 130B-1b, 130B-2, and 130B-3 are separated from each other in the top view as shown in FIG. 16. Furthermore, the middle portions of the package components 20 are not covered by any of the heat spreader layers 130B-1a, 130B-1b, 130B-2, and 130B-3 in accordance with some embodiments.

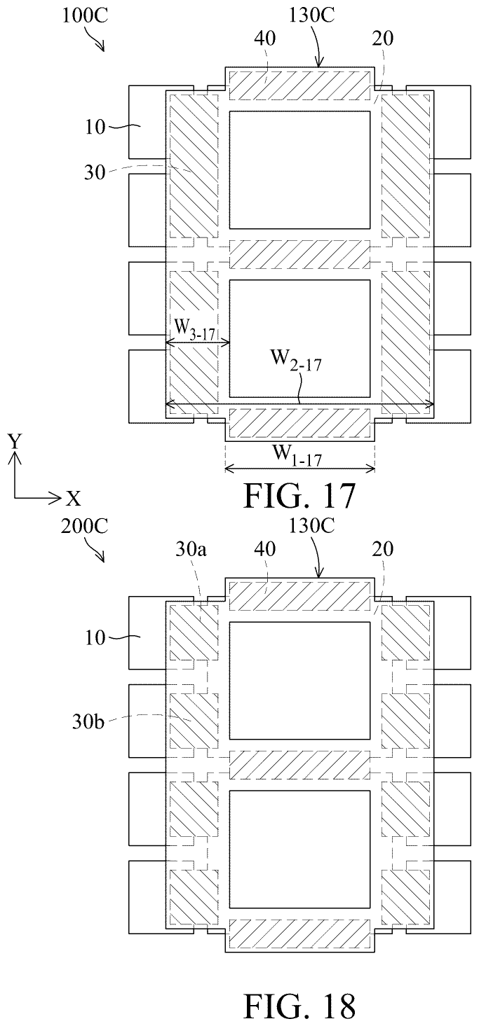

FIG. 17 illustrates a diagrammatic top view of a package structure 100C in accordance with some embodiments. The package structure 100C may be similar to the package structure 100 described previously, except the shape of its heat spreader layer is different in accordance with some embodiments. Processes and materials for forming the package structure 100C may be similar to, or the same as, those for forming the package structures 100, 100A, and 100B described previously and are not repeated herein.

As shown in FIG. 17, the package structure 100C includes the package components 10 and 20 and the semiconductor dies 30 and 40 in accordance with some embodiments. In addition, a heat spreader layer 130C is formed over the semiconductor dies 30 and 40, so that the heat generate by the semiconductor dies 30 and 40 during the operation can be dissipated and the temperature of the device may be reduced. In some embodiments, the semiconductor dies 30 and 40 are completely covered by the heat spreader layer 130C. In some embodiments, the heat spreader layer 130C has first portions vertically overlapping the semiconductor dies 30 and second portions vertically overlapping the semiconductor dies 40, and the first portions and the second portions are connected with each other.

In some embodiments, a middle portion of each of the package component 20 is not overlapped with the heat spreader layer 130C, while a peripheral portion of each of the package component 20 is overlapped with the heat spreader layer 130C in the top view as shown in FIG. 17. In some embodiments, the heat spreader layer 130C has a first width W₁₋₁₇, a second width W₂₋₁₇, and a third width W₃₋₁₇ measured along the X direction. In addition, the second width W₂₋₁₇ is greater than both the first width W₁₋₁₇ and the third width W₃₋₁₇ in accordance with some embodiments. In some embodiments, the first width W₁₋₁₇ is greater than the third width W₃₋₁₇.

In some embodiments, the package components 10 and 20 are partially covered by the heat spreader layer 130C. The processes for forming the heat spreader layer 130C may be similar to, or the same as, the processes for forming the heat spreader layer 130A described previously, except the heat spreader layer 130C is mainly formed over the semiconductor dies 30 and 40.

FIG. 18 illustrates a diagrammatic top view of a package structure 200C in accordance with some embodiments. The package structure 200C may be similar to the package structure 200A described previously, except the shape of its heat spreader layer is different in accordance with some embodiments. Processes and materials for forming the package structure 200C may be similar to, or the same as, those for forming the package structures 200, 200A, and 200B described previously and are not repeated herein.

As shown in FIG. 18, the heat spreader layer 130C is formed over the semiconductor dies 30a, 30b, and 40 in accordance with some embodiments. The processes for forming the heat spreader layer 130C may be similar to, or the same as, the processes for forming the heat spreader layer 130A described previously, except the heat spreader layer 130C is mainly formed over the semiconductor dies 30a, 30b, and 40, respectively. In some embodiments, the semiconductor dies 30a, 30b, and 40 are completely covered by the heat spreader layer 130C. Furthermore, the middle portions of the package components 20 are not covered by the heat spreader layer 130C in accordance with some embodiments.

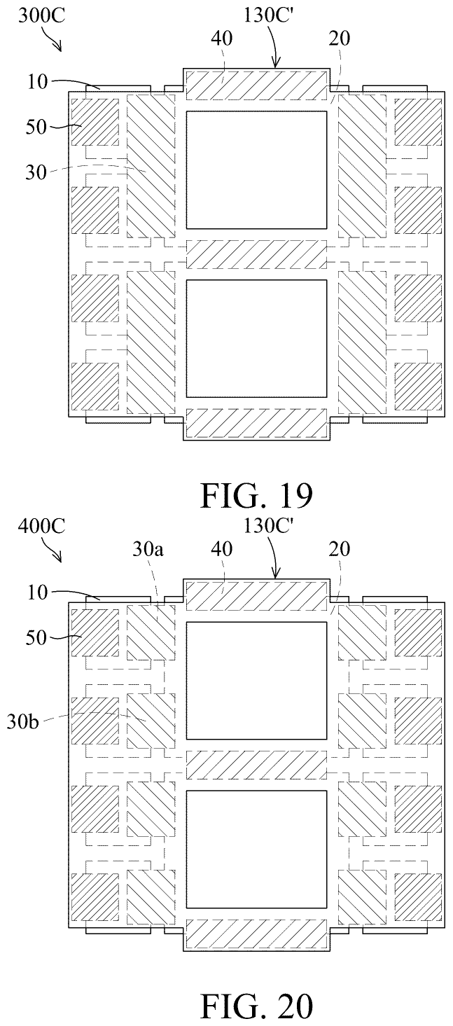

FIG. 19 illustrates a diagrammatic top view of a package structure 300C in accordance with some embodiments. The package structure 300C may be similar to the package structure 300A described previously, except the shape of its heat spreader layer is different in accordance with some embodiments. Processes and materials for forming the package structure 300C may be similar to, or the same as, those for forming the package structures 300, 300A, and 300B described previously and are not repeated herein.

As shown in FIG. 19, a heat spreader layer 130C′ is formed over the semiconductor dies 30, 40, and 50 in accordance with some embodiments. The processes for forming the heat spreader layer 130C′ may be similar to, or the same as, the processes for forming the heat spreader layer 130A described previously, except the heat spreader layer 130C′ is mainly formed over the semiconductor dies 30, 40, and 50. Furthermore, the middle portions of the package components 20 are not covered by the heat spreader layer 130C′ in accordance with some embodiments.

FIG. 20 illustrates a diagrammatic top view of a package structure 400C in accordance with some embodiments. The package structure 400C may be similar to the package structure 400A described previously, except the shape of its heat spreader layer is different in accordance with some embodiments. Processes and materials for forming the package structure 400C may be similar to, or the same as, those for forming the package structures 400, 400A, and 400B described previously and are not repeated herein. As shown in FIG. 20, the heat spreader layer 130C′ is formed over the semiconductor dies 30a, 30b, 40, and 50 in accordance with some embodiments. Furthermore, the middle portions of the package components 20 are not covered by the heat spreader layer 130C′ in accordance with some embodiments.

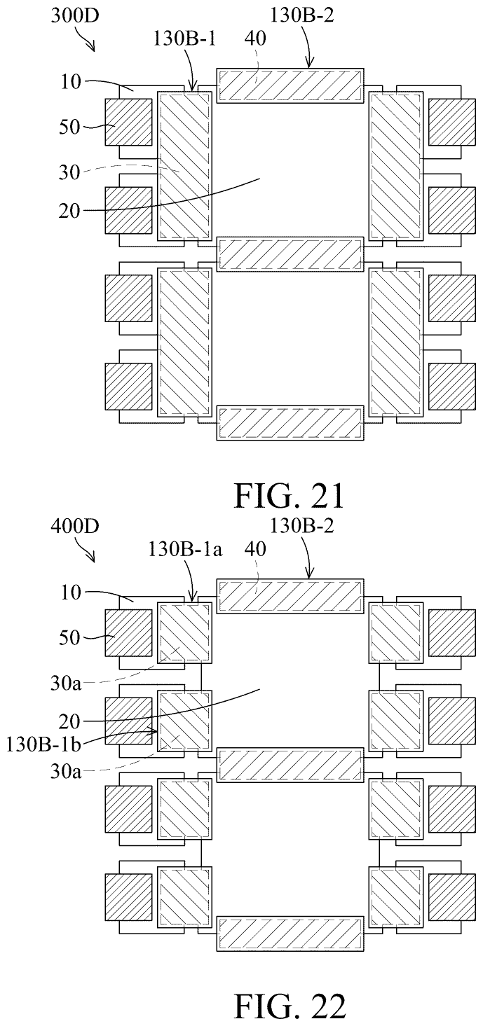

FIG. 21 illustrates a diagrammatic top view of a package structure 300D in accordance with some embodiments. The package structure 300D may be similar to the package structure 300 described previously, except the shape of its heat spreader layer is different in accordance with some embodiments. Processes and materials for forming the package structure 300D may be similar to, or the same as, those for forming the package structures 300, 300A, 300B, and 300C described previously and are not repeated herein.

As shown in FIG. 21, the package structure 300D includes the package components 10 and 20 and the semiconductor dies 30, 40, and 50 in accordance with some embodiments. In addition, the heat spreader layers 130B-1 and 130B-2 are formed over the semiconductor dies 30 and 40 but are not formed over the semiconductor dies 50 in accordance with some embodiments. Furthermore, the middle portions of the package components 20 are not covered by any of the heat spreader layers 130B-1 and 130B-2 in accordance with some embodiments.

FIG. 22 illustrates a diagrammatic top view of a package structure 400D in accordance with some embodiments. The package structure 400D may be similar to the package structure 400 described previously, except the shape of its heat spreader layer is different in accordance with some embodiments. Processes and materials for forming the package structure 400D may be similar to, or the same as, those for forming the package structures 400, 400A, 400B, and 400C described previously and are not repeated herein.

As shown in FIG. 22, the package structure 400D includes the package components 10 and 20 and the semiconductor dies 30a, 30b, 40, and 50 in accordance with some embodiments. In addition, the heat spreader layers 130B-1a, 130B-1b, and 130B-2 are formed over the semiconductor dies 30a, 30b, and 40 but are not formed over the semiconductor dies 50 in accordance with some embodiments. Furthermore, the middle portions of the package components 20 are not covered by any of the heat spreader layers 130B-1a, 130B-1b, and 130B-2 in accordance with some embodiments.

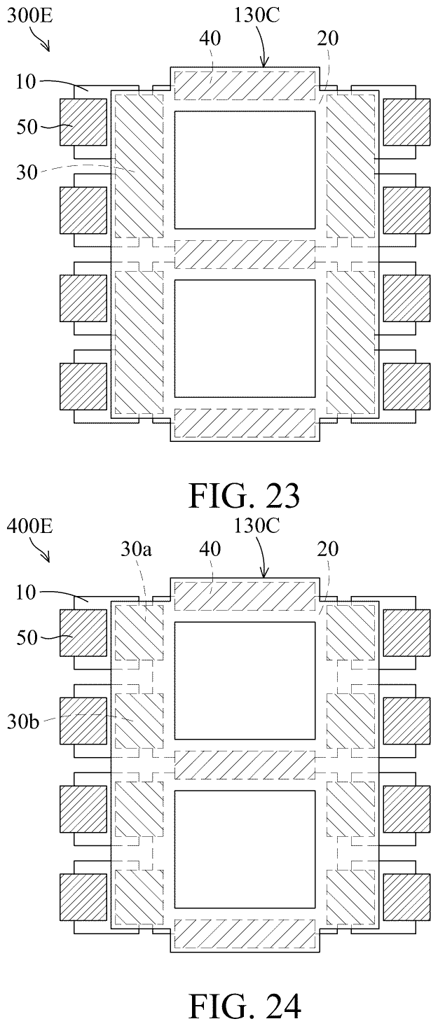

FIG. 23 illustrates a diagrammatic top view of a package structure 300E in accordance with some embodiments. The package structure 300E may be similar to the package structure 300 described previously, except the shape of its heat spreader layer is different in accordance with some embodiments. Processes and materials for forming the package structure 300E may be similar to, or the same as, those for forming the package structures 300, 300A, 300B, 300C, and 300D described previously and are not repeated herein.

As shown in FIG. 23, the package structure 300E includes the package components 10 and 20 and the semiconductor dies 30, 40, and 50 in accordance with some embodiments. In addition, the heat spreader layer 130C is formed over the semiconductor dies 30 and 40 but are not formed over the semiconductor dies 50 in accordance with some embodiments. Furthermore, the middle portions of the package components 20 are not covered by the heat spreader layer 130C in accordance with some embodiments.

FIG. 24 illustrates a diagrammatic top view of a package structure 400E in accordance with some embodiments. The package structure 400E may be similar to the package structure 400 described previously, except the shape of its heat spreader layer is different in accordance with some embodiments. Processes and materials for forming the package structure 400E may be similar to, or the same as, those for forming the package structures 400, 400A, 400B, 400C, and 400D described previously and are not repeated herein.

As shown in FIG. 24, the package structure 400E also include the package components 10 and 20 and the semiconductor dies 30a, 30b, 40, and 50 in accordance with some embodiments. In addition, the heat spreader layer 130C is formed over the semiconductor dies 30a, 30b, and 40 but are not formed over the semiconductor dies 50 in accordance with some embodiments. Furthermore, the middle portions of the package components 20 are not covered by the heat spreader layer 130C in accordance with some embodiments.

As described above, the semiconductor dies (e.g. the semiconductor dies 30, 30a, 30b, 40, and 50) may be formed to be electrically connected to the package components (e.g. the package components 10 and 20) through the redistribution structure (e.g. the redistribution structure 108). However, during operation, the semiconductor dies may generate heat. Therefore, the heat spreader layer (e.g. the heat spreader layer 130, 130A, 130A′, 130B-1, 130B-2, 130B-1a, 130B-1b, 130B-3, 130C, and 130C′) are formed over the semiconductor dies, so that the heat generated by the semiconductor dies may be spread (e.g. dissipate) laterally. Accordingly, the temperature of the package structures, especially at the hot spots around the semiconductor dies, may be reduced, and the performance of the package structures may therefore be improved.

It should be appreciated that the elements shown in the package structures 100, 100′, 200, 300, 400, 100A, 100A′, 200A, 300A, 300A′, 400A, 400A′, 100B, 100B′, 200B, 300B, 400B, 100C, 100C′, 200C, 300C, 400C,300D, 400D, 300E, and 400E may be combined and/or exchanged. For example, the conductive features formed in the heat spreader layers (e.g. the heat spreader layer 130, 130A, 130A′, 130B-1, 130B-2, 130B-1a, 130B-1b, 130B-3, 130C, and 130C′) in the package structures may have the structures shown in FIG. 2P-1, 2P-2, 4A, 4B, 5A, or 5B, although the layout of the package structures may be different.

In addition, it should be noted that same elements in FIGS. 1A to 24 may be designated by the same numerals and may include materials that are the same or similar and may be formed by processes that are the same or similar; therefore such redundant details are omitted in the interests of brevity. In addition, although FIGS. 1A to 24 are described in relation to the method, it will be appreciated that the structures disclosed in FIGS. 1A to 24 are not limited to the method but may stand alone as structures independent of the method. Similarly, the methods shown in FIGS. 1A to 24 are not limited to the disclosed structures but may stand alone independent of the structures.

Also, while the disclosed methods are illustrated and described above as a series of acts or events, it should be appreciated that the illustrated ordering of such acts or events may be altered in some other embodiments. For example, some acts may occur in a different order and/or concurrently with other acts or events apart from those illustrated and/or described above. In addition, not all illustrated acts may be required to implement one or more aspects or embodiments of the description above. Furthermore, one or more of the acts depicted above may be carried out as one or more separate acts and/or phases.

Furthermore, the terms “approximately,” “substantially,” “substantial” and “about” used above account for small variations and may be varied in different technologies and be within the deviation range understood by the skilled in the art. For example, when used in conjunction with an event or circumstance, the terms can refer to instances in which the event or circumstance occurs precisely as well as instances in which the event or circumstance occurs in a close approximation.

Embodiments of package structures may be provided. The package structure may include package components and semiconductor dies disposed at opposite sides of a redistribution structure. In addition, a heat spreader layer is formed over the semiconductor dies, so that the heat generate by the semiconductor dies may be spread laterally by the heat spreader layer. Accordingly, the temperature of the device during operation may be reduced, and the performance may be improved.

A package structure is provided. The package structure includes a first redistribution structure and a first package component and a second package component attached to a first side of the first redistribution structure and spaced apart from each other in a first direction. The package structure further includes a first semiconductor die attached to a second side of the first redistribution structure and an encapsulant formed around the first semiconductor die. The package structure further includes a heat spreader layer formed over the first semiconductor die, and a thermal conductivity of the heat spreader layer is greater than a thermal conductivity of the encapsulant. The package structure further includes a conductive feature formed through the heat spreader layer and a second redistribution structure formed over the heat spreader layer. In addition, the second retribution structure is electrically connected to the first semiconductor die through the conductive feature.

A package structure is provided. The package structure includes a first semiconductor die having a first projection area in a top view and a first redistribution structure attached to a first side of the first semiconductor die. The package structure further includes a heat spreader layer attached to a second side of the first semiconductor die, and the heat spreader layer has a second projection area in the top view, and the second projection area of the heat spreader layer is greater than the first projection area of the first semiconductor die. The package structure further includes a second redistribution structure formed over the heat spreader layer and a conductive feature formed through the heat spreader layer and electrically connecting the first semiconductor die and the second redistribution structure. The package structure further includes a first package component and a second package component attached to the first redistribution structure. In addition, the first semiconductor die partially overlaps both the first package component and the second package component.

A method for forming a package structure is provided. The method for forming a package structure includes disposing a first semiconductor die over a first carrier substrate and forming a first redistribution structure over a first side of the first semiconductor die. The method for forming a package structure further includes disposing a first package component and a second package component over the first distribution structure. In addition, the first package component is spaced apart from the second package component in a first direction. The method for forming a package structure further includes attaching a second carrier substrate over the first package component and the second package component and removing the first carrier substrate from a second side of the first semiconductor die. The method for forming a package structure further includes forming a heat spreader layer covering the second side of the first semiconductor die, and the heat spreader layer is made of a carbon-containing material, and a width of the heat spreader layer is greater than a width of the first semiconductor die in the first direction. The method for forming a package structure further includes forming a first conductive feature through the heat spreader layer and forming a second redistribution structure covering the heat spreader layer and the first conductive feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package device, comprising:
a first redistribution structure;
a plurality of package components attached to a first side of the first redistribution structure;
a plurality of semiconductor dies attached to a second side of the first redistribution structure opposite to the first side;
a heat spreader layer formed over the plurality of semiconductor dies;
a second redistribution structure over the heat spreader layer; and
a plurality of conductive features extending through the heat spreader layer and electrically connecting the plurality of semiconductor dies to the second redistribution structure.

2. The semiconductor package device of claim 1, wherein the heat spreader layer comprises graphene or diamond-like carbon.

3. The semiconductor package device of claim 1, wherein at least one of the plurality of semiconductor dies partially overlaps at least two of the plurality of package components.

4. The semiconductor package device of claim 1, further comprising an encapsulant surrounding the plurality of semiconductor dies, wherein a thermal conductivity of the heat spreader layer is greater than a thermal conductivity of the encapsulant.

5. The semiconductor package device of claim 1, wherein at least one of the plurality of conductive features has a sloped sidewall surface in direct contact with the heat spreader layer.

6. The semiconductor package device of claim 1, wherein at least one of the plurality of conductive features has a convex top surface in contact with the second redistribution structure.

7. The semiconductor package device of claim 1, wherein the heat spreader layer is in direct contact with a substrate of at least one of the plurality of semiconductor dies.

8. A package structure, comprising:
a first redistribution structure and a second redistribution structure;
a semiconductor die vertically interposed between the first redistribution structure and the second redistribution structure;
a heat spreader layer between the semiconductor die and the second redistribution structure, wherein the heat spreader layer is in direct contact with a substrate of the semiconductor die; and
a conductive feature extending through the heat spreader layer and electrically connecting a conductive via in the semiconductor die to a conductive path in the second redistribution structure.

9. The package structure of claim 8, further comprising a dielectric layer adjacent to the heat spreader layer, wherein a bottommost layer of the second redistribution structure has a protruding portion laterally between the conductive feature and the heat spreader layer.

10. The package structure of claim 8, wherein the second redistribution structure comprises a plurality of insulating layers and a plurality of redistribution layers, and wherein a thermal conductivity of the heat spreader layer is greater than a thermal conductivity of the insulating layers.

11. The package structure of claim 8, wherein the heat spreader layer comprises a carbon-containing material having a thermal conductivity in a range from 1 W/m-K to 1000 W/m-K.

12. The package structure of claim 8, wherein the heat spreader layer comprises graphene or diamond-like carbon.

13. The package structure of claim 8, wherein the heat spreader layer has a thickness in a range from 10 μm to 30 μm.

14. A semiconductor device, comprising:
a first semiconductor structure, the first semiconductor structure having a first conductive feature;
an encapsulant adjacent sidewalls of the first semiconductor structure, the encapsulant having a first surface and a second surface;
a heat spreader layer over the first semiconductor structure;
a dielectric layer over the first surface of the encapsulant and adjacent to the heat spreader layer;
a first redistribution structure on the heat spreader layer and the dielectric layer, the first redistribution structure having a second conductive feature; and
a third conductive feature extending through the heat spreader layer to electrically couple the first conductive feature of the first semiconductor structure to the second conductive feature of the first redistribution structure.

15. The semiconductor device of claim 14, wherein a width of the third conductive feature is greater than a width of the first conductive feature of the first semiconductor structure.

16. The semiconductor device of claim 14, further comprising:
a second redistribution structure over the second surface of the encapsulant; and
a second semiconductor structure mounted on the second redistribution structure, wherein the second redistribution structure is between the first semiconductor structure and the second semiconductor structure.

17. The semiconductor device of claim 14, wherein the heat spreader layer comprises a carbon-containing material.

18. The semiconductor device of claim 17, wherein the heat spreader layer comprises graphene or diamond-like carbon.

19. The semiconductor device of claim 14, wherein the heat spreader layer completely covers the first semiconductor structure in a plan view.

20. The semiconductor device of claim 14, further comprising:
a second semiconductor structure adjacent to the first semiconductor structure, wherein the heat spreader layer extends continuously from over the first semiconductor structure to over the second semiconductor structure.
